(19) United States
(12) Patent Application Publication
(10) Pub. No.: US 2018/0225403 A1
(43) Pub. Date: Aug. 9, 2018

(54) DYNAMIC CONFIGURATION OF A RECONFIGURABLE HUM FABRIC

(71) Applicant: Wave Computing, Inc., Campbell, CA (US)

(72) Inventors: Christopher John Nicol, Campbell, CA (US); Shaishav Desai, San Jose, CA (US)

(21) Appl. No.: 15/941,741

(22) Filed: Mar. 30, 2018

Related U.S. Application Data
(63) Continuation-in-part of application No. 15/691,254, filed on Aug. 30, 2017.
Application No. 15/691,254 is a continuation-in-part of application No. 15/475,411, filed on Mar. 31, 2017, now Pat. No. 9,960,771.
(60) Provisional application No. 62/399,745, filed on Sep. 26, 2016.
(60) Provisional application No. 62/315,779, filed on Mar. 31, 2016.

(51) Int. Cl. G06F 17/50; H03K 19/00

(52) U.S. Cl. CPC G06F 17/5054; G06F 2217/62; H03K 19/0008

(57) ABSTRACT

Techniques are disclosed for circuit configuration. Information is obtained on logical distances between reconfigurable fabric circuits on a semiconductor chip. A plurality of clusters is identified within the reconfigurable fabric circuits on the semiconductor chip. A cycle count separation across the plurality of cluster is evaluated using information on the logical distances. A plurality of counter initializations is calculated where the counter initializations compensate for the cycle count separation across the clusters. A plurality of counters is initialized, with a counter from the plurality of counters being associated with each cluster from the plurality of clusters, where the counters are distributed across the clusters, and where the initializing is based on the counter initializations that were calculated. The plurality of counters is started to coordinate configuration across the plurality of clusters. Logical configuration of the clusters as a function of the initializing of the counters is enabled.

### RELATED APPLICATIONS

This application is a continuation-in-part of U.S. patent application “Program Counter Alignment across a Reconfigurable Hum Fabric” Ser. No. 15/691,254, filed Aug. 30, 2017, which claims the benefit of U.S. provisional patent application “Program Counter Alignment across a Reconfigurable Hum Fabric” Ser. No. 62/399,745, filed Sep. 26, 2016. This application is also a continuation in part of U.S. patent application “Hum Generation Using Representative Circuitry” Ser. No. 15/475,411, filed Mar. 31, 2017, which claims the benefit of U.S. provisional patent application “Hum Generation Using Representative Circuitry” Ser. No. 62/315,779, filed Mar. 31, 2016.

Each of the foregoing applications is hereby incorporated by reference in its entirety.

### FIELD OF ART

This application relates generally to circuit configuration and more particularly to dynamic configuration of a reconfigurable hum fabric.

### BACKGROUND

Electronic circuits are used in a wide variety of applications and products for many purposes, including communication, audio/video, security, general and special purpose computing, data compression, signal processing, and medical devices, to name a few. Current consumer trends focus on increasingly powerful devices with increased portability. It can prove challenging to achieve more processing power while simultaneously improving energy efficiency. Improved energy efficiency translates to longer battery life, which is an important factor in the design of portable electronic devices. To enable complex functionality along with efficiency in power consumption, designers often utilize a system-on-chip (SoC). SoCs are constructed using a variety of modules and/or sub-systems used to perform specific functions. These are integrated together with a communication medium (such as a system bus). Each module could have different timing requirements. The integration of modules with varying clock and timing requirements can create challenges in design, testing, and verification of complex SoCs.

Circuit synchronization and timing are important considerations in the design of a complex circuit or SoC. In practice, the arrival time of a signal can vary for many reasons. The various values placed on input data can cause different operations or calculations to be performed, introducing a delay in the arrival of a signal. Furthermore, operating conditions such as temperature can affect the speed at which circuits may perform. Variability in the manufacture of parts can also contribute to timing differences. Properties such as the threshold voltage of transistors, the width of metallization layers, and dopant concentrations are examples of parameters that can vary during the production of integrated circuits, potentially affecting timing. A large-scale architecture with many subsystems can typically result in a large number and variety of interacting clock domains. Synchronizing all of the clock domains can be rendered difficult by engineering costs, power consumption, and project-level risks. Accordingly, such architectures and designs increasingly utilize multiple asynchronous clock domains. The use of a variety of different domains can make timing analysis and synchronization even more challenging.

The electronic systems with which people interact on a daily basis contain electronic integrated circuits or “chips”. The chips result from stringent specifications and are designed to perform a wide variety of functions in the electronic systems. The chips support and enable the electronic systems to perform their functions effectively and efficiently. The chips are based on highly complex circuit designs, system architectures and implementations, and fabrication processes. The chips are integral to the electronic systems. The chips implement functions such as communications, processing, and networking, whether the electronic systems are applied to business, entertainment, or consumer electronics purposes. The electronic systems routinely contain more than one chip. The chips implement critical functions including power management, audio codecs, computation, storage, and control. The chips compute algorithms and heuristics, handle and process data, communicate internally and externally to the electronic system, and so on. Since there are so many computations that must be performed, any improvements in the efficiency of the computations have a significant and substantial impact on overall system performance. As the amount of data to be handled increases, the approaches that are used must be not only effective, efficient, and economical, but must also be scalable.

### SUMMARY

Disclosed embodiments provide for dynamic configuration of a reconfigurable hum fabric. Information can be obtained on logical distances between reconfigurable fabric circuits on a semiconductor chip. A plurality of clusters can be identified within the reconfigurable fabric circuits on the semiconductor chip. A cycle count separation across the plurality of clusters can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters.

Reconfigurable arrays or clusters that include processing elements, switching elements, clusters of clusters, etc., have many applications where high-speed data transfer and processing are advantageous. Global distribution of signals such as clocks, data, controls, status flags, etc. are often required for proper system operation. However, the reconfigurable arrays, including a reconfigurable fabric, may not support such distribution because of physical limitations of design styles, system architectures, fabrication capabilities, etc. Instead, the global signals can be propagated across the reconfigurable arrays or fabric. Propagation can be based on determining how to initialize the reconfigurable fabric in order to most efficiently propagate the global signals. The propagation can be based on hum generation signals.

Disclosed is a processor-implemented method for circuit configuration comprising: obtaining information on logical distances between reconfigurable fabric circuits on a semiconductor chip; identifying a plurality of clusters within the reconfigurable fabric circuits on the semiconductor chip, wherein a cluster within the plurality of clusters is synchronized to a cycle; evaluating a cycle count separation across the plurality of clusters using the information on the logical distances; calculating a plurality of counter initializations wherein the counter initializations compensate for the cycle count separation across the plurality of clusters; initializing a plurality of counters, with a counter from the plurality of counters being associated with a cluster from the plurality of clusters, wherein the plurality of counters is distributed across the plurality of clusters, and wherein the initializing is based on the counter initializations that were calculated; and starting the plurality of counters to coordinate configuration across the plurality of clusters.

Some embodiments further comprise enabling logical configuration of the plurality of clusters as a function of the initializing of the plurality of counters. Some embodiments further comprise performing a logical operation using the reconfigurable fabric based on the logical configuration. In embodiments, the logical operation is different from a previous logical operation that was performed using the reconfigurable fabric before the starting of the plurality of counters. In embodiments, the plurality of clusters is within a superset of clusters on the reconfigurable fabric. In embodiments, only the plurality of clusters within the superset of clusters is reconfigured.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for dynamic configuration of a reconfigurable hum fabric.

FIG. 2 is a flow diagram for logical configuration.

FIG. 3 is a 3×3 cluster illustrating program counter settings.

FIG. 4 shows an 8×8 group of clusters with count distances.

FIG. 5 illustrates communication between clusters.

FIG. 6 is a flow diagram for cold boot and run-time active states.

FIG. 7A illustrates counters decrementing as start propagates.

FIG. 7B shows counters decrementing to zero.

FIG. 8 shows an example block diagram of representative circuits.

FIG. 9 shows an example schematic of a timing circuit.

FIG. 10A shows clusters entering configuration mode.

FIG. 10B shows clusters exiting configuration mode.

FIG. 11 shows a cluster for coarse-grained reconfigurable processing.

FIG. 12 shows a block diagram of a circular buffer.

FIG. 13 illustrates a circular buffer and processing elements.

FIG. 14 is a system for dynamic circuit reconfiguration.

### DETAILED DESCRIPTION

Techniques are disclosed for circuit configuration, and more particularly for dynamic configuration of a reconfigurable hum fabric. Reconfigurable fabrics that run at a very fast hum frequency can provide an extremely powerful dataflow processing system for handling massive amounts of data and calculations, such as that required for machine learning, deep analytics, and other big data applications. The electronics and semiconductor industries are compelled by commercial, military, and other market segments to improve the semiconductor chips and systems that they design, develop, implement, fabricate, and deploy. Improvements of the semiconductor chips are measured based on many factors including design criteria such as the price, dimensions, speed, power consumption, heat dissipation, feature sets, compatibility, etc. These chip measurements are implemented into designs of the semiconductor chips and the capabilities of the electronic systems that are built from the chips. The semiconductor chips and systems are deployed in many market segments including commercial, medical, consumer, educational, financial, etc. The applications include computation, digital communications, control and automation, etc., naming only a few. The abilities of the chips to perform basic logical operations and to process data, at high speed, are fundamental to any of the chip and system applications. The abilities of the chips to transfer very large data sets have become particularly critical because of the demands of many applications. Disclosed embodiments provide fundamental improvements to the architectures and chips used for processing big data applications, such as machine learning.

Chip, system, and computer architectures have traditionally relied on controlling the flow of data through the chip, system, or computer. In these architectures, such as the classic Van Neumann architecture where memory is shared for storing instructions and data, a set of instructions is executed to process data. With such an architecture, referred to as a “control flow”, the execution of the instructions can be predicted and can be deterministic. That is, the way in which data is processed is dependent upon the point in a set of instructions at which a chip, system, or computer is operating. In contrast, a “dataflow” architecture is one in which the data controls the order of operation of the chip, system, or computer. The dataflow control can be determined by the presence or absence of data. Dataflow architectures find applications in many areas including the fields of networking and digital signal processing, as well as other areas in which large data sets must be handled, such as telemetry and graphics processing.

Dataflow processors can be applied to many applications where large amounts of data such as unstructured data are processed. Typical processing applications for unstructured data can include speech and image recognition, natural language processing, bioinformatics, customer relationship management, digital signal processing (DSP), graphics processing (GP), network routing, telemetry such as weather data, data warehousing, and so on. Dataflow processors can be programmed using software and can be applied to highly advanced problems in computer science such as deep learning. Deep learning techniques can include an artificial neural network, a convolutional neural network, etc. The success of these techniques is highly dependent on large quantities of data for training and learning. The data-driven nature of these techniques is well suited to implementations based on dataflow processors. The dataflow processor can receive a dataflow graph such as an acyclic dataflow graph, where the dataflow graph can represent a deep learning network. The dataflow graph can be assembled at runtime, where assembly can include calculation input/output, memory input/output, and so on. The assembled dataflow graph can be executed on the dataflow processor.

The dataflow processors can be organized in a variety of configurations. One configuration can include processing element quads with arithmetic units. A dataflow processor can include one or more processing elements (PE). The processing elements can include a processor, a data memory, an instruction memory, communications capabilities, and so on. Multiple PEs can be grouped, where the groups can include pairs, quads, octets, etc. The PEs arranged in arrangements such as quads can be coupled to arithmetic units, where the arithmetic units can be coupled to or included in data processing units (DPU). The DPUs can be shared between and among quads. The DPUs can provide arithmetic techniques to the PEs, communications between quads, and so on.

The dataflow processors, including dataflow processors arranged in quads, can be loaded with kernels. The kernels can be a portion of a dataflow graph. In order for the dataflow processors to operate correctly, the quads can require reset and configuration modes. Processing elements can be configured into clusters of PEs. Kernels can be loaded onto PEs in the cluster, where the loading of kernels can be based on availability of free PEs, an amount of time to load the kernel, an amount of time to execute the kernel, and so on. Reset can begin with initializing up-counters coupled to PEs in a cluster of PEs. Each up-counter is initialized with a value minus one plus the Manhattan distance from a given PE in a cluster to the end of the cluster. A Manhattan distance can include a number of steps to the east, west, north, and south. A control signal can be propagated from the start cluster to the end cluster. The control signal advances one cluster per cycle. When the counters for the PEs all reach 0 then the processors have been reset. The processors can be suspended for configuration, where configuration can include loading of one or more kernels onto the cluster. The processors can be enabled to execute the one or more kernels. Configuring mode for a cluster can include propagating a signal. Clusters can be preprogrammed to enter configuration mode. A configuration mode can be entered. Various techniques, including direct memory access (DMA) can be used to load instructions from the kernel into instruction memories of the PEs. The clusters that were pre-programmed into configuration mode can be preprogrammed to exit configuration mode. When configuration mode has been exited, execution of the one or more kernels loaded onto the clusters can commence. In embodiments, clusters can be reprogrammed and during the reprogramming switch instructions used for routing are protected so that routing continues through a cluster.

Dataflow processes that can be executed by dataflow processor can be managed by a software stack. A software stack can include a set of subsystems, including software subsystems, which may be needed to create a software platform. A complete software platform can include a set of software subsystems required to support one or more applications. A software stack can include both offline and online operations. Offline operations can include software subsystems such as compilers, linker simulators, emulators, and so on. The offline software subsystems can be included in a software development kit (SDK). The online operations can include dataflow partitioning, dataflow graph throughput optimization, and so on. The online operations can be executed on a session host and can control a session manager. Online operations can include resource management, monitors, drivers, etc. The online operations can be executed on an execution engine. The online operations can include a variety of tools which can be stored in an agent library. The tools can include BLAS™, CONV2D™ SoftMax™, and so on.

Software to be executed on a dataflow processor can include precompiled software or agent generation. The pre-compiled agents can be stored in an agent library. An agent library can include one or more computational models which can simulate actions and interactions of autonomous agents. Autonomous agents can include entities such as groups, organizations, and so on. The actions and interactions of the autonomous agents can be simulated to determine how the agents can influence operation of a whole system. Agent source code can be provided from a variety of sources. The agent source code can be provided by a first entity, provided by a second entity, and so on. The source code can be updated by a user, downloaded from the Internet, etc. The agent source code can be processed by a software development kit, where the software development kit can include compilers, linkers, assemblers, simulators, debuggers, and so on. The agent source code that can be operated on by the software development kit can be located in an agent library. The agent source code can be created using a variety of tools, where the tools can include MATMUL™, Batchnorm™, Relu™, and so on. The agent source code that has been operated on can include functions, algorithms, heuristics, etc., that can be used to implement a deep learning system.

A software development kit can be used to generate code for the dataflow processor or processors. The software development kit can include a variety of tools which can be used to support a deep learning technique or other technique which requires processing of large amounts of data such as unstructured data. The SDK can support multiple machine learning techniques such as machine learning techniques based on GEMM™, sigmoid, and so on. The SDK can include a low-level virtual machine (LLVM) which can serve as a front end to the SDK. The SDK can include a simulator. The SDK can include a Boolean satisfiability solver (SAT solver). The SDK can include an architectural simulator, where the architectural simulator can simulate a dataflow processor or processors. The SDK can include an assembler, where the assembler can be used to generate object modules. The object modules can represent agents. The agents can be stored in a library of agents. Other tools can be included in the SDK. The various techniques of the SDK can operate on various representations of a flow graph.

Direct memory access can be applied to improve communication between processing elements, switching elements etc. of a fabric or cluster of such elements. Since communication such as the transfer of data from one location to another location can be a limiting factor in system performance, increased communication rate and efficiency can directly impact speed. Data is obtained from a first switching element within a plurality of switching elements. The first switching element is controlled by a first circular buffer. The data is sent to a second switching element within the plurality of switching elements. The second switching element is controlled by a second circular buffer. The obtaining data from the first switching element and the sending data to the second switching element includes a direct memory access. The first switching element and the second switching element can be controlled by a third switching element within the plurality of switching elements.

A circuit according to disclosed embodiments is configured to provide hum generation such that the circuit can operate at a hum frequency. A hum frequency can be a frequency at which multiple clusters within the circuit self-synchronize to each other. The hum generation circuit can be referred to as a fabric. The hum generation fabric can form a clock generation structure. Each module contains one or more functional circuits such as adders, shifters, comparators, and/or flip flops, among others. These functional circuits each perform a function over a finite period of time. The operating frequency of a module is bounded by the slowest functional circuit within the module. In embodiments, each functional circuit operates over one cycle or tic of the clock. The cycle, or tic cycle, can be a single cycle of the hum generated self-clocking signal. With a self-clocking design, it can be a challenge to select a hum frequency that is compatible with each of the various functional logic circuits within each cluster. If the hum frequency is not correct, then the overall operation of the integrated circuit might be compromised.

Often, a function being executed by various kernels loaded across a reconfigurable fabric needs to be updated or changed before the execution of the task embodied in the kernels is completed. For example, a task could be a machine learning task as represented by a data flow graph and implemented using weights derived for a neural network. In order to efficiently and dynamically configure the fabric with minimal latency, one or more kernels may be replaced, or reloaded, into one or more clusters of processors within the reconfigurable fabric. It is then of critical importance to be able to start, or restart, the fabric in proper synchronization, which is accomplished using the disclosed techniques for dynamic configuration of a reconfigurable hum fabric. The configuration, or reconfiguration, can occur without interruption of other kernels executing within the reconfigurable hum fabric.

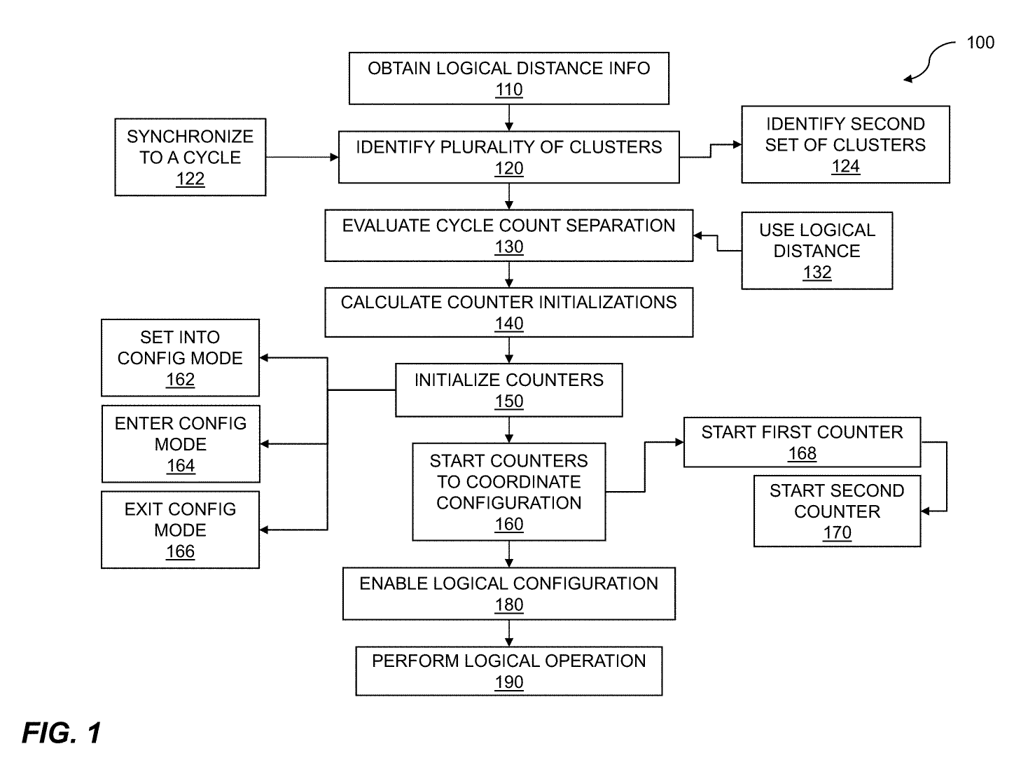

FIG. 1 is a flow diagram for dynamic configuration of a reconfigurable hum fabric. Information can be obtained on logical distances between reconfigurable fabric circuits on a semiconductor chip. A plurality of clusters can be identified within the reconfigurable fabric circuits on the semiconductor chip. A cycle count separation across the plurality of clusters can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters. The flow 100 includes obtaining information on logical distances 110 between circuits on a semiconductor chip. Logical distance can include Manhattan distances, where distances can be determined based on steps taken to the north, south, east, or west. Manhattan distances do not support diagonal moves per se. Instead, distances are determined by taking a step to the north or south and a step to the east or west (i.e. two steps).

The flow 100 includes identifying a plurality of clusters 120 within the circuits on the semiconductor chip. Semiconductor chips can include many circuits, where the circuits can be simple or complex, digital or analog, etc. One or more of the circuits can include a reconfigurable fabric on the semiconductor chip. The reconfigurable fabric can include processing elements, switching elements, interface elements, etc. In embodiments, an element can be configured to be a processing element, a switching element, an interface element, a storage element, and so on. A cluster can include a region within the semiconductor chip. The semiconductor chip can include one or more clusters, and the clusters can be grouped together. The clusters can communicate with their nearest neighbors, where the nearest neighbors can be a Manhattan step away. The communications can include control, data, configuration data, etc. A cluster within the plurality of clusters can be synchronized to a cycle boundary 122. Multiple clusters can be synchronized to the same cycle boundary, to different cycle boundaries, and so on. The reconfigurable fabric can be synchronized by hum generation signals. The flow 100 can include identifying a second set of clusters 124 if more than one kernel needs to be replaced or updated.

The flow 100 includes evaluating a cycle count separation 130 across the plurality of clusters using the information on the logical distances 132. The logical distance can be based on Manhattan distances as described above. The cycle count separation can be based on the number of processing elements (PE), number of clusters, etc., in a group. In embodiments, the cycle count separation between two neighboring clusters, from the plurality of clusters, can be a single cycle count. The single cycle count can correspond to a Manhattan step (north, south, east, or west). In other embodiments, the cycle count separation between two neighboring clusters, from the plurality of clusters, can be a two cycle count. A neighboring cluster located on a diagonal can be two Manhattan steps away. For example, for a 3×3 group, the cycle count separation between the block in the southwestern-most corner and the northeastern-most corner can be five since the count to the southwestern-most corner is one from cluster zero. Further, at least one cycle can occur in order for one or more operations to be performed. The cycle count separation can be determined based on Manhattan distances. Other distance geometries can be included that can be based on diagonal distances. The logical distances comprise sequential cycle counts. In embodiments, the information on logical distances is calculated based on Manhattan geometry. In embodiments, the cycle for the cluster is a tic cycle boundary. In embodiments, a cycle, from the cycle count separation, can define alignment edges for synchronized operation of logic. Propagation timing can be based on a deterministic value that can include a propagation timing equal to one cycle. Other propagation timing values can be included.

The flow 100 includes calculating a plurality of counter initializations 140 where the counter initializations compensate for the cycle count separation across the plurality of clusters. Returning to the 3×3 group example, and by referencing discussions presented elsewhere, the counter initializations of elements of a group depend on the location of a particular element within the group. The element can be a processing element, a switching element, a cluster, and so on. Count separations for processing elements within a cluster, clusters within clusters, etc., can be determined based on Manhattan distances or other separations. The one or more counters can be initialized based on the location of the processing element or cluster position within a cluster. As discussed in the 3×3 example above and elsewhere, the counter initializations can vary from five in the southwestern-most cluster or PE, to one in the northeastern-most cluster or PE. Note that the counter initializations can be equal along northwest-to-southeast diagonals in the clusters.

The flow 100 includes initializing a plurality of counters 150, with a counter from the plurality of counters being associated with each cluster from the plurality of clusters, where the counters from the plurality of counters are distributed across the plurality of clusters, and where the initializing is based on the counter initializations that were calculated. The counters can be initialized on the Manhattan distance. The counters can be initialized based on cycle count separation. One counter, from the plurality of counters, can be located in each of the plurality of clusters. Multiple counters can be located in each of the plurality of clusters. Various types of counters can be used. In embodiments, the plurality of counters comprises down counters. The plurality of counters can be set to specific values, based on the logical distances, at time of boot for the semiconductor chip. The setting of the counters at time of boot can be used to reset the fabric, initialize the fabric, and so on. In embodiments, the specific values can provide for synchronized startup of operation across a reconfigurable fabric. The initializing can include memory accesses to values such as initialization values for the counters. In embodiments, the initializing of the plurality of counters can occur during hardware paging. In embodiments, the counter initialization includes setting the counters into configuration mode 162 to stop the kernel from executing and prepare the kernel clusters to enter configuration mode. The entering configuration mode 164 allows a new kernel to be loaded into the clusters. The clusters can be loaded via DMA operation. Once the new kernel is loaded, the clusters can exit configuration mode 166, at which point their program counter or counters are restarted in synchronization to allow the new kernel, along with the other existing kernels, to operate or continue to operate, as described below.

The flow 100 includes starting the plurality of counters 160 to coordinate calculation across the plurality of clusters. The counters can be used to control propagation of signals including propagated global signals, status signals, data, and so on. The counters can be started as a result of a reset of processing elements, a reset of switching elements, a reset of clusters, etc. The starting the plurality of counters can include starting a first counter 168 in a first cluster, from the plurality of clusters, followed by starting a second counter 170 in a second cluster, from the plurality of clusters. The starting counters can include starting a third counter in a third cluster, and so on. In embodiments, the second cluster can be a neighboring cluster, from the plurality of clusters, to the first cluster. Other counters can be started to coordinate calculation across the plurality of clusters, whether the clusters are adjacent or not. Various embodiments of the flow 100 may be included in a computer program product embodied in a non-transitory computer readable medium that includes code executable by one or more processors.

The flow 100 includes enabling the logical configuration 180 of the plurality of clusters as a function of the initializing of the plurality of counters. The synchronized start of the cluster or clusters enables performing the logical operation 190 described in the new kernel, along with the restarting, or continuing, operations of any other related kernels. Various steps in the flow 100 may be changed in order, repeated, omitted, or the like without departing from the disclosed concepts. Various embodiments of the flow 100 may be included in a computer program product embodied in a non-transitory computer readable medium that includes code executable by one or more processors.

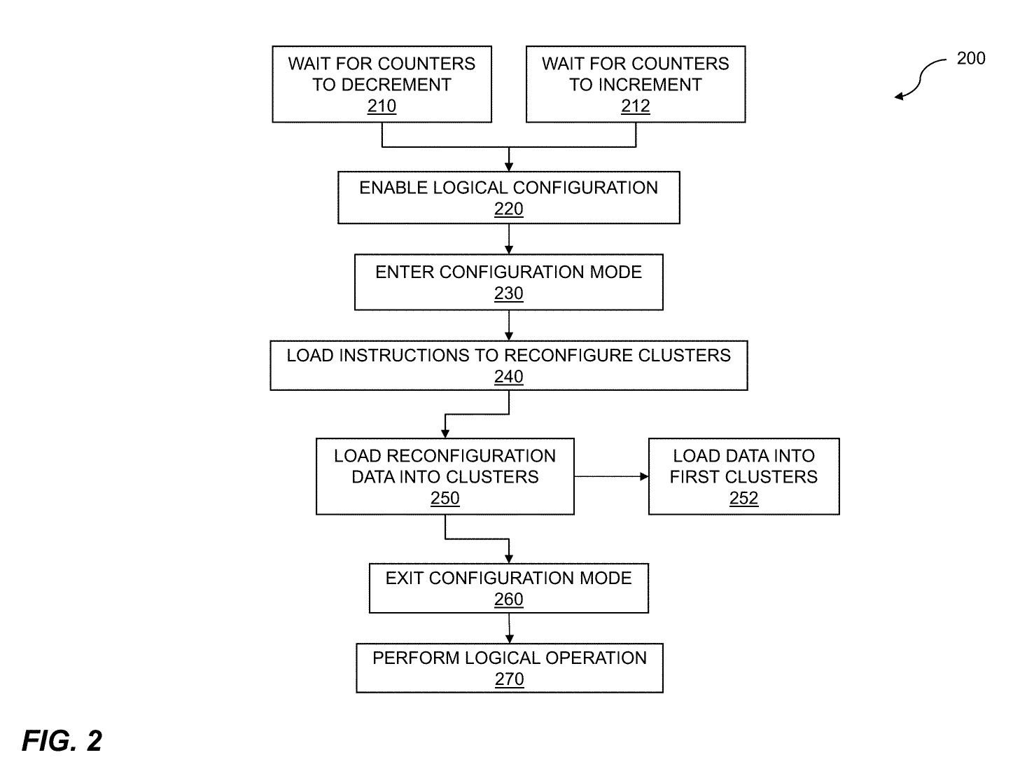

FIG. 2 is a flow diagram for logical configuration. The flow 200 includes waiting for counters to decrement 210 or waiting for counters to increment 212. The counters can also be reset to all zeros, to all ones, to an initialization code, etc. Resetting of the counters can result from a global reset signal being propagated across a cluster of processing elements, a cluster of clusters, etc. In embodiments, the plurality of counters can be reset prior to the initializing (see element 150 above). The flow 200 includes enabling a logical configuration 220. When the counters increment or decrement to a specified value, or in at least one embodiment, when the counters reach zero, the processors associated with the counters are suspended (i.e., not executing the kernel) and enter configuration mode 230. The flow 200 includes loading instructions to reconfigure the clusters to support a new kernel 240. The loading can include loading reconfiguration data into the clusters 250, and/or loading data into the first clusters 252.

In embodiments, the instructions are loaded into circular buffers. The instructions include direct memory access instructions that direct clusters to accept reconfiguration data. The instructions cause a first set of clusters to execute instructions from internal memory. In embodiments, the internal memory is a read-only memory. Data can likewise be loaded into a second one or more clusters (not shown). In embodiments, counters within the second clusters are excluded from initialization during the initializing. In embodiments, the second set of clusters continues execution of instructions while the plurality of clusters is reconfigured. The flow 200 includes exiting configuration mode 260 after the clusters have been updated. After synchronization, the cluster is restarted for performing a logical operation 270 associated with the new or updated kernel resident on the cluster. Calculation across the plurality of clusters can be stopped, based on values included in the initializing the plurality of counters. The calculations can be stopped based on counter values being decremented to zero, invalid data, empty data, an internal halt signal, and external halt signal, and so on. Stopping calculation can result from receiving a signal to place one or more clusters into a sleep state. In embodiments, the enabling logical configuration of the clusters as a function of the initializing of the counter comprises waiting for the counters to decrement to a predetermined value. In embodiments, all the clusters decrement to the same predetermined value. In embodiment, the predetermined value is zero. In embodiments, the enabling logical configuration of the clusters as a function of the initializing of the counter comprises waiting for the counters to increment to a predetermined value.

In embodiments, one or more switching elements, processing elements, clusters, etc., of one or more clusters of switching elements, etc., can be placed into a sleep state. A switching element can enter a sleep state based on processing an instruction that places the switching element into the sleep state. The switching element can be woken from the sleep state as a result of valid data being presented to the switching element of a cluster. Recall that a given switching element can be controlled by a circular buffer. The circular buffer can contain an instruction to place one or more of the switching elements into a sleep state. The circular buffer can remain awake while the switching element controlled by the circular buffer is in a sleep state. In embodiments, the circular buffer associated with the switching element can be placed into the sleep state along with the switching element. The circular buffer can wake along with its associated switching element. The circular buffer can wake at the same address as when the circular buffer was placed into the sleep state, at an address that can continue to increment while the circular buffer was in the sleep state, etc. The circular buffer associated with the switching element can continue to cycle while the switching element is in the sleep state, but instructions from the circular buffer may not be executed. The sleep state can include a rapid transition to sleep state capability, where the sleep state capability can be accomplished by limiting clocking to portions of the switching elements. In embodiments, the sleep state can include a slow transition to sleep state capability, where the slow transition to sleep state capability can be accomplished by powering down portions of the switching elements. The sleep state can include a low power state.

The obtaining data from a first switching element and the sending the data to a second switching element can include a direct memory access (DMA). A DMA transfer can continue while valid data is available for the transfer. A DMA transfer can terminate when it has completed without error, or when an error occurs during operation. Typically, a cluster that initiates a DMA transfer will request to be brought out of sleep state when the transfer is completed. This waking is achieved by setting control signals that can control the one or more switching elements. Once the DMA transfer is initiated with a start instruction, a processing element or switching element in the cluster can execute a sleep instruction to place itself to sleep. When the DMA transfer terminates, the processing elements and/or switching elements in the cluster can be brought out of sleep after the final instruction is executed. Note that if a control bit can be set in the register of the cluster that is operating as a slave in the transfer, that cluster can also be brought out of sleep state (if it is asleep during the transfer).

The cluster that is involved in a DMA and can be brought out of sleep after the DMA terminates can determine that it has been brought out of a sleep state based on the code that is executed. A cluster can be brought out of a sleep state based on the arrival of a reset signal and the execution of a reset instruction. The cluster can be brought out of sleep by the arrival of valid data (or control) following the execution of a switch instruction. A processing element or switching element can determine why it was brought out of a sleep state by the context of the code that the element starts to execute. A cluster can be awoken during a DMA operation by the arrival of valid data. The DMA instruction can be executed while the cluster remains asleep as the cluster awaits the arrival of valid data. Upon arrival of the valid data, the cluster is woken and the data stored. Accesses to one or more data random access memories (RAM) can be performed when the processing elements and the switching elements are operating. The accesses to the data RAMs can also be performed while the processing elements and/or switching elements are in a low power sleep state. Various steps in the flow 200 may be changed in order, repeated, omitted, or the like without departing from the disclosed concepts. Various embodiments of the flow 200 may be included in a computer program product embodied in a non-transitory computer readable medium that includes code executable by one or more processors.

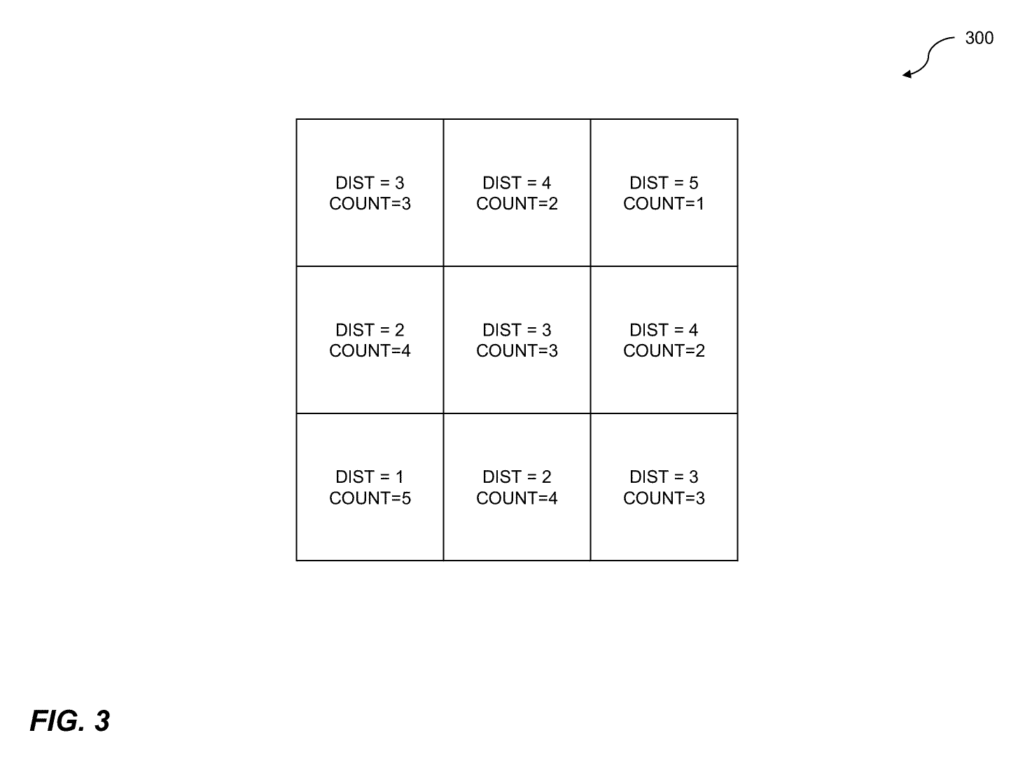

FIG. 3 is a 3×3 cluster illustrating program counter settings. Information can be obtained on logical distances between reconfigurable fabric circuits on a semiconductor chip. A plurality of clusters can be identified within the reconfigurable fabric circuits on the semiconductor chip. A cycle count separation across the plurality of cluster can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters. A semiconductor chip can include a large number of circuits. The circuits can be organized into clusters for various purposes including reconfiguration, programming, control, etc. A cluster can include a region within the semiconductor chip. The semiconductor chip can include one cluster, a few clusters, many clusters, and so on. A cluster of circuits on a semiconductor chip can include a reconfigurable fabric on the semiconductor chip. Global signals including clock, data, status, control, etc., by design may not be distributed across the reconfigurable fabric or the semiconductor chip, yet such signals can be critical to the operation of the clusters and the semiconductor chip. Such global signals can be distributed across the semiconductor chip via a propagation technique. Synchronization of signal propagation is critical to effective chip operation. The reconfigurable fabric can be synchronized by hum generation signals.

A global signal to be propagated across a cluster, multiple clusters, the semiconductor chip, and so on, originates as an event. To propagate the global signals, a propagator can be used to rebroadcast any timed global signal. Each propagator can perform various operations including those that: contain a programmed value indicating its Manhattan distance from cluster zero; receive a signal assertion as input from one or more cardinal directions (north, south, east, or west); contain a countdown register, loaded with a reset value upon assertion of a signal input, where the reset value can be a function of its Manhattan distance value and a maximum value distance; ignore the assertion of any other propagated global signal when a countdown is currently in progress; and act upon the signal's meaning only when the countdown register reaches zero.

A timed global signal can be asserted in the southwestern-most propagator 300. The southwestern-most corner can have a Manhattan distance of one from the origin cluster, cluster zero. Since the northeastern-most corner is an additional four steps using Manhattan distance, then the count in the southwestern-most corner is calculated to be five. The count can be used by a program counter which can be used to control propagation. The counts and distances for the remaining cells similarly can be calculated. The distance values increase while the count values decrease. Note that the count values are equal and distance values are equal along northwest-to-southeast diagonals because the cells along the diagonals are equidistant from the southwestern-most cell in a Manhattan distance sense.

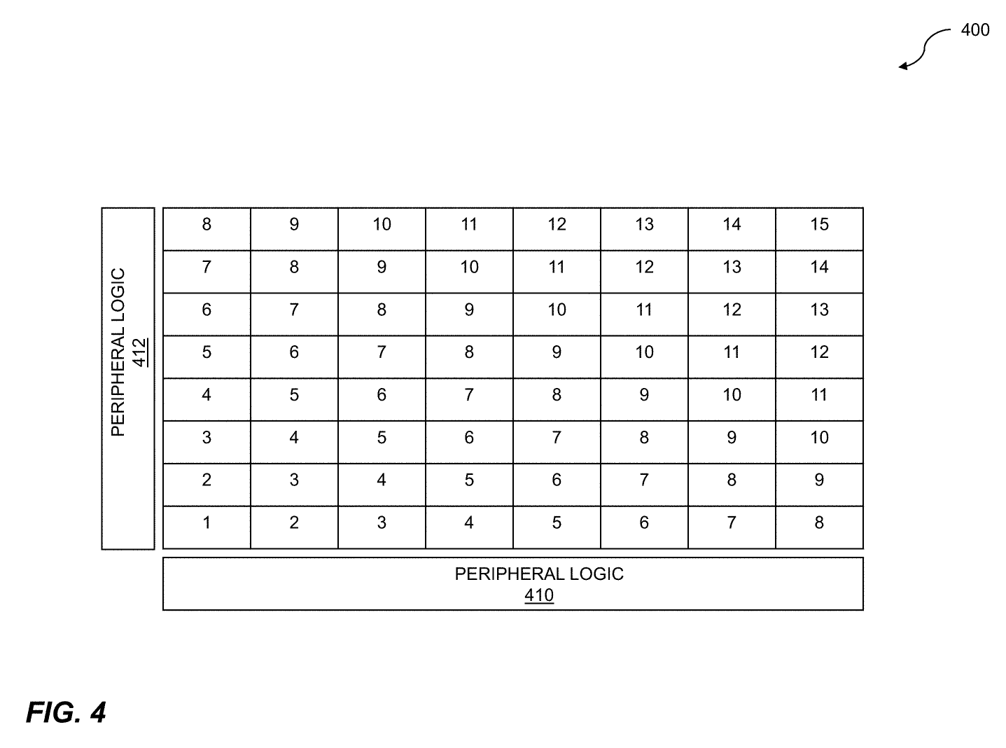

FIG. 4 shows an 8×8 group of clusters with count distances 400. Information can be obtained on logical distances between reconfigurable fabric circuits on a semiconductor chip. A plurality of clusters can be identified within the reconfigurable fabric circuits on the semiconductor chip. A cycle count separation across the plurality of clusters can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters. As described above, a semiconductor chip can include a large number of circuits, clusters, and so on. A cluster of circuits on a semiconductor chip can include a reconfigurable fabric on the semiconductor chip. The clusters can be determined for various purposes including data handling, reconfiguration, programming, control, etc. The number of clusters on the semiconductor chip can be dependent upon the purpose of the chip, its architecture, its design style, and so on.

Some signals that can be utilized by the semiconductor chip can be required across the entire chip. These global signals can include data, control, clock, status, etc. The design of the chip can directly impact distribution of these global signals due to limitations on physical design such as the numbers of layers of interconnect. The global signals can be distributed across the semiconductor chip via a propagation technique. Synchronization of signal propagation is critical to effective chip operation. The reconfigurable fabric can be synchronized by hum generation signals.

An 8×8 group of clusters included in an example semiconductor chip is shown with count distances. Signals including global signals can be coupled to the 8×8 group using peripheral logic. The peripheral logic can include peripheral logic that couples vertically to the 8×8 group 410, and can include peripheral logic that couples horizontally to the 8×8 group 412. Since global signals such as clock, data, control, status etc., may not be physically available globally, these global signals can be propagated across the 8×8 group of clusters. In order to perform the signal propagation, the count distances to various clusters can be calculated. The count distances can be based on Manhattan distances, where one count step can be made to the north, south, east, or west. The count distance to the southwestern-most cell is calculated to be one since it is one step from the origin cluster zero. To get to the other clusters within the 8×8 group of clusters, steps can be counted from the southwestern-most corner of the 8×8 group. So, a step to the north, south, east or west counts as one step, while a step along a diagonal from southwest-to northeast counts as two steps, one step to the east or west, and one step to the north or south. By proceeding through the 8×8 group of clusters, the Manhattan distances to each cluster from the southwestern-most cluster can be calculated. Note that clusters along northwest-to-southeast diagonals have equal count distances.

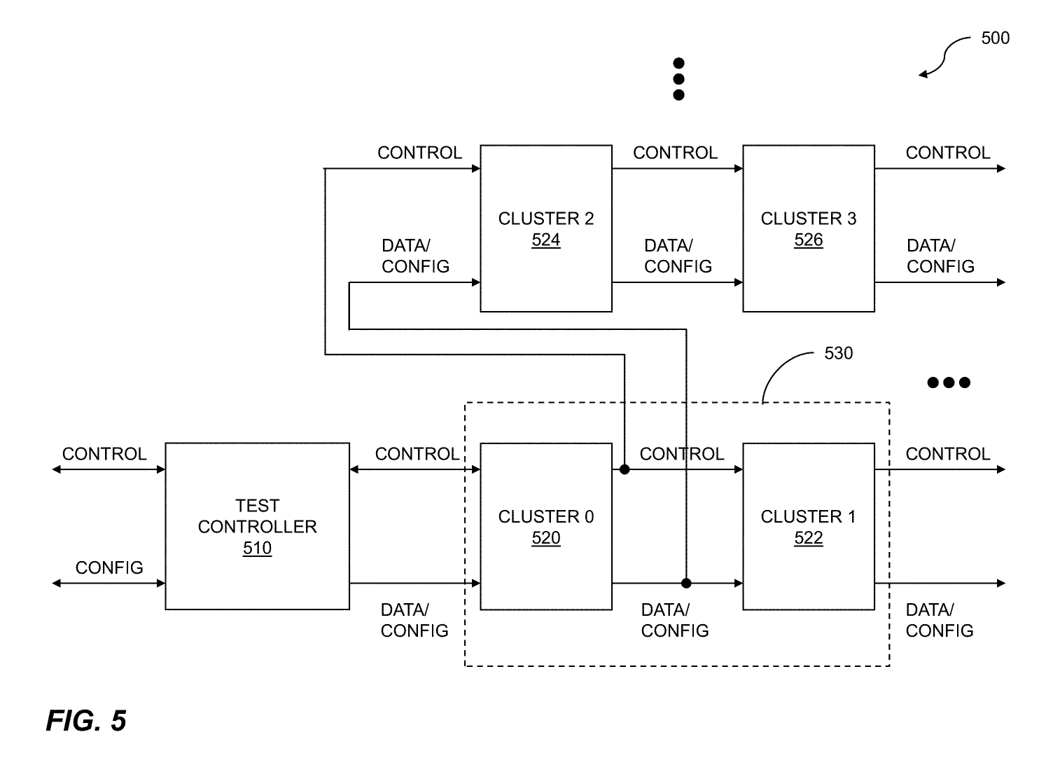

FIG. 5 illustrates communication between clusters 500. Information can be obtained on logical distances between reconfigurable fabric circuits on a semiconductor chip. A plurality of clusters can be identified within the reconfigurable fabric circuits on the semiconductor chip. A cycle count separation across the plurality of cluster can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters. Semiconductor chips include a wide variety of circuits, where the circuits can include clusters. The clusters can include a region within the semiconductor chip. In embodiments, the circuits can include a reconfigurable fabric on the semiconductor chip. Clusters of circuits can be organized into groups, and communication among the clusters can be established.

Communication between and among clusters is shown. A test controller 510 can receive control/configuration signals and can communicate control, data and/or configuration signals to clusters. Since communications can be based on Manhattan directions and distances, a given cluster may communicate with neighboring clusters that are located to the north, south, east or west of the given cluster. Communications can include control and data configuration signals that can be communicated by the test controller 510. The test controller can communicate with cluster 0 520. Cluster 0 520 can communicate with its neighbors to the east, cluster 1 522, and north, cluster 2 524, since cluster 0 is the southwestern-most cluster. Cluster 1 522 can communicate with its neighbor clusters (not shown) by communicating control and data configuration signals. Cluster 2 524 can communicate with cluster 3 526 which is one of its possible neighbors. Control and data configuration signals can be similarly propagated to other clusters (not shown).

Clusters can operate at a hum frequency. A hum frequency can be a frequency at which multiple clusters within the circuit self-synchronize to each other. The hum generation circuit can be referred to as a fabric. The hum generation fabric can form a clock generation structure. In embodiments, a subset of clusters can participate in the hum. For example, in illustration 500, cluster 0 520 and cluster 1 522 can comprise subset 530. Thus, the effective fabric for certain operations can be smaller than the fully utilized fabric. In such cases, the smaller fabric facilitates power management. In embodiments, a rectangular subset of clusters, such as subset 530, participates. In other embodiments, a square subset of clusters participates. Other participating subsets of clusters within the fabric are also possible.

The subsets of clusters can be defined by loading variables via a serial scan chain (not shown). The variables can be loaded before the chips are started, thus controlling which subset or subsets of clusters will participate in the hum generation fabric. The subset of clusters uses less power than the whole fabric of clusters, which can be very valuable for managing power distribution, packaging noise, thermal dissipation and cooling, simultaneous switching noise, software program interfaces, and the like. In some embodiments, the configuration is dynamically changed during runtime. The scan chains can be loaded with zones of subsets of clusters. The zones represent various subsets of clusters that can be used for various operations. A configuration scan chain can be loaded with the contents of the previous scan chain. The operation of a subset of clusters can then be suspended, and the configuration scan chain can then be loaded with the contents of the initial scan chain. Thus, the cluster can be configured at the speed of the hum fabric without huge latencies to reconfigure the zones of subsets of clusters. In yet further embodiments, the suspension of operations is pended until the next instruction 0 is encountered. In this way, the process is waiting until instruction 0 is encountered and the elements of the clusters used for the next fabric operation can be included with, or excluded from, as the case may be, a new subset of clusters.

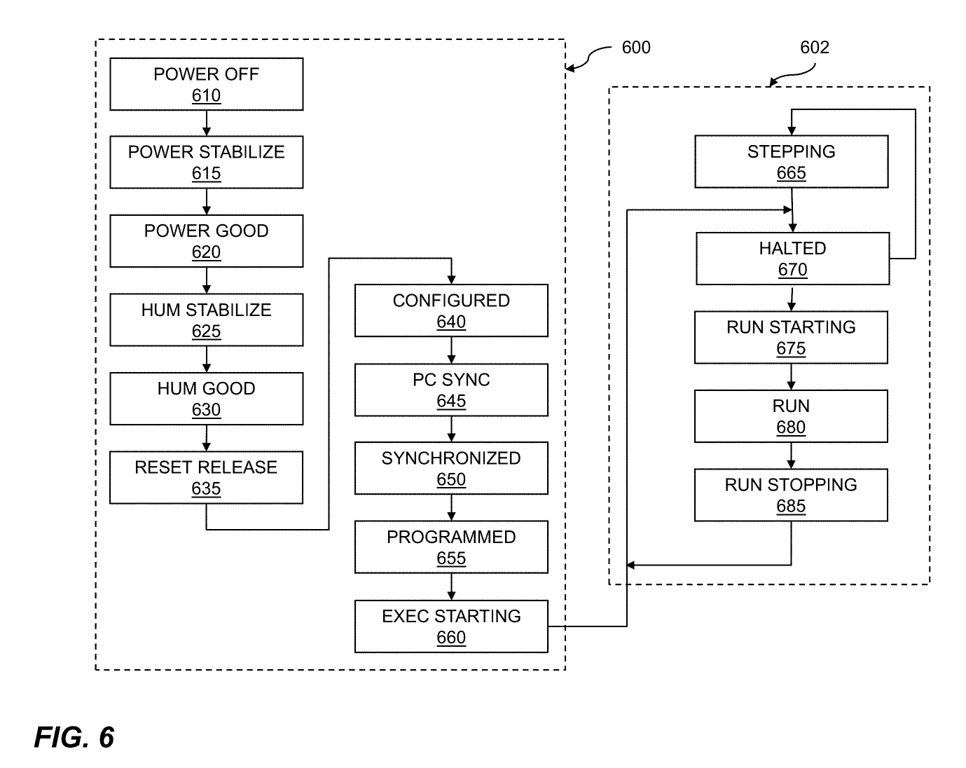

FIG. 6 is a flow diagram for cold boot and run-time active states. Information can be obtained on logical distances between reconfigurable fabric circuits on a semiconductor chip. A plurality of clusters can be identified within the reconfigurable fabric circuits on the semiconductor chip. A cycle count separation across the plurality of cluster can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters. As discussed above, a semiconductor chip can include many circuits, and some or all of the circuits can include a reconfigurable fabric on the semiconductor chip. A cluster can include a region within the semiconductor chip. To keep the semiconductor chip, the circuits, the reconfigurable fabric, the clusters, etc. operating properly, synchronization can be performed. In embodiments, the reconfigurable fabric can be synchronized by hum generation signals.

The reconfigurable fabric can include operational states. The fabric can be in only one of a limited number of states, where the states can include temporary states and where the transition from the temporary state can be automatic. Other transitions from a state can require that an internal or an external event occur in order for the transition to be executed. The operational states can include power off, power stabilize, power good, hum clocks stabilize, configured, and so on. Other states can also be included. The operational states can be formed into groups, where the groups can include a cold boot process 600 and runtime active states 602.

The cold boot process begins from power off 610. Power can be applied the fabric, where the application of power can include ramping the power. The power can stabilize 615. Free-running oscillators that generate hum clocks can be running although may not yet be synchronized. A power good 620 state can be reached. Hum stabilize 625 can occur after a time period. The time period can be based on a system timer. Hum good 630 can occur when the timer has expired. With hum good asserted, a reset signal can be deasserted. The deassertion of reset signal can be indicative of a reset release 635 state being reached. The fabric can be configured 640. Configuration can occur at boot time and can include setting default routing paths, setting cluster identifications (IDs), setting a counter reset value, etc. Program counters (PC's) can be synchronized 645. Program counters across the entire fabric can be synchronized 650 and can begin executing at PC zero. With the fabric synchronized, the fabric can be programmed. Programming can include writing all instructions to the fabric. Programming can include initialization of processing element registers, memories, etc. Programming can conclude with reaching the programmed state 655. Completion of programming can assert an execute starting signal 660.

Runtime active states 602 can result from initializing and programming the fabric. The fabric can remain in a halted state 670 with switches and direct memory access (DMA) active. Further programming can occur. In order to execute processing element instructions, a propagated global signal run starting 675 can be sent to begin executing instructions starting at program counter (PC) zero. Executing instructions can include the run state 680. Occurrence of an external halt signal or an internal halt can cause the fabric to enter a run stopping 685 state. Processing elements can stop executing instructions. Stepping 665 can occur as part of a debugging technique. Various steps in the cold boot process flow 600 and the runtime active states flow 602 may be changed in order, repeated, omitted, or the like without departing from the disclosed concepts. Various embodiments of the cold boot process flow 600 and the runtime active states flow 602 may be included in a computer program product embodied in a non-transitory computer readable medium that includes code executable by one or more processors.

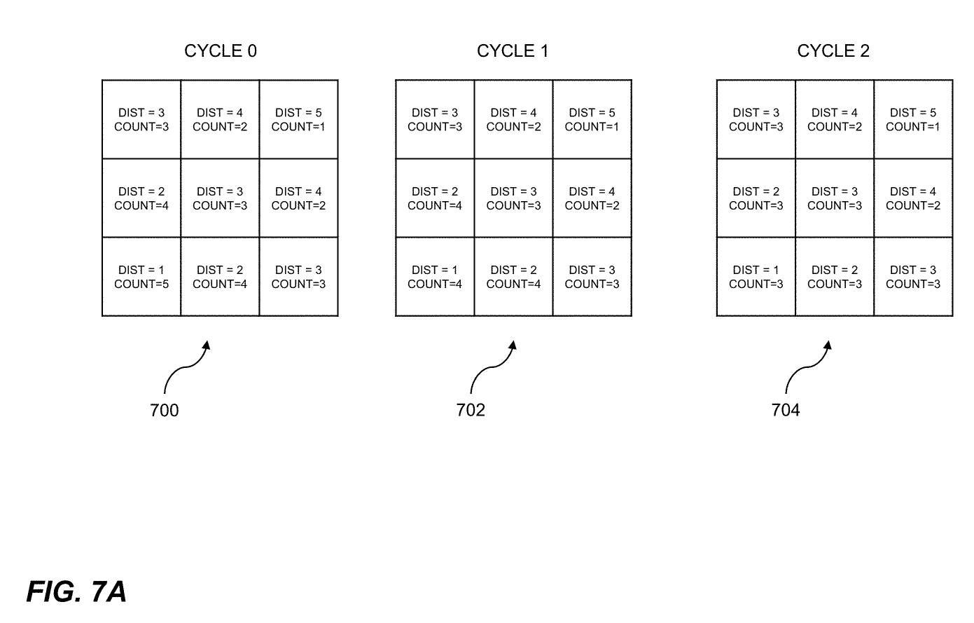

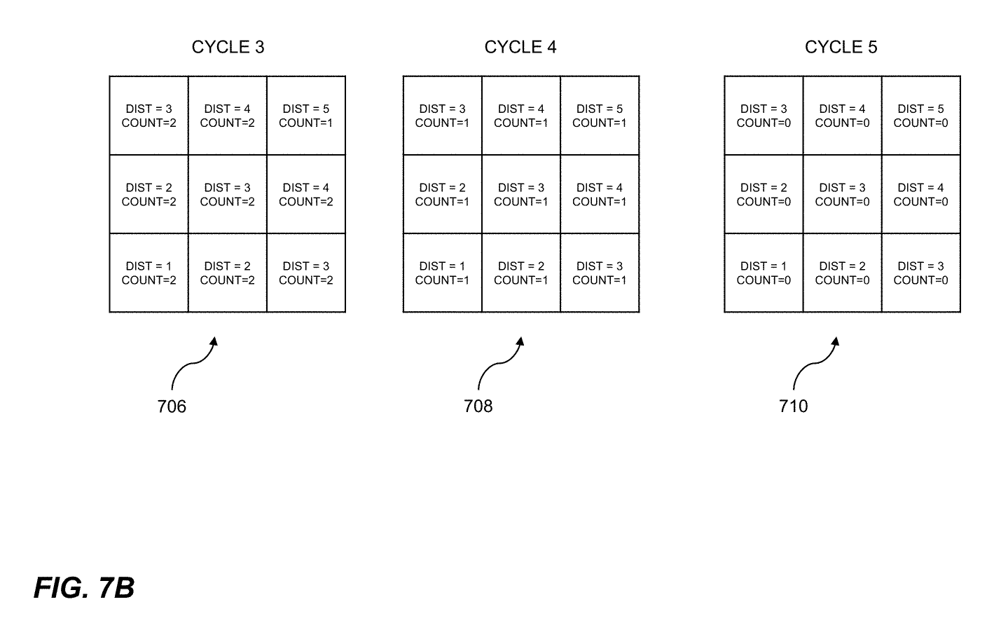

FIG. 7A illustrates counters decrementing as start propagates. Information on logical distances between circuits on a semiconductor chip can be obtained. A plurality of clusters within the circuits on the semiconductor chip can be determined, where a cluster within the plurality of clusters can be synchronized to a cycle boundary. A plurality of counter initializations can be calculated, where the counter initializations can compensate for the cycle count separation across the plurality of clusters. A plurality of counters can be initialized, with a counter from the plurality of counters being associated with each cluster from the plurality of clusters, where the counters from the plurality of counters can be distributed across the plurality of clusters, and where the initializing can be based on the counter initializations that were calculated. The plurality of counters can be started to coordinate calculation across the plurality of clusters. Circuits on a semiconductor chip can include a reconfigurable fabric on the semiconductor chip. The reconfigurable fabric can include processing elements, switching elements, interface elements, and so on. Typically, digital systems require signals such as power, ground, clocks, data, status, etc., that are available globally across the semiconductor chip. The reconfigurable fabric may not support a physical global presence of such signals but can support a logical global presence of the signals. These global signals can be distributed by propagating the signals across the reconfigurable fabric.

To propagate global signals across the reconfigurable fabric, each propagated global signal originates as an event. To propagate the global signals, a propagator can be used to rebroadcast any timed global signal that is received by the propagator. Each propagator can: contain a programmed value indicating its Manhattan distance from cluster zero; receive a signal assertion as input from one or more cardinal directions (north, south, east, or west); contain a countdown register, loaded with a reset value upon assertion of a signal input, where the reset value can be a function of its Manhattan distance value and a maximum value distance; ignore the assertion of any other propagated global signal when a countdown is currently in progress; and act upon the signal's meaning only when the countdown register reaches zero.

A timed global signal can be asserted in the southwestern-most propagator 700. The southwestern-most corner can have a Manhattan distance of 1 from the origin cluster, cluster zero. Since the northeastern-most corner is an additional 4 steps using Manhattan distance, then the count in the southwestern-most corner is 5. The counts and distances for the remaining cells can be calculated. Note that the counts and distances are equal along diagonals from northwest to southeast because the cells along the diagonals are equidistant from the southwestern-most cell in a Manhattan distance sense. As propagation proceeds, the count in the southwestern-most cell is decremented by 1, making the count equal for the southwestern-most cell and its adjacent diagonal 702. Propagation continues, and the counts are decremented from 4s to 3s 704. Propagation continues until the counts in all cells are zero.

FIG. 7B shows counters decrementing to zero. Information on logical distances between circuits on a semiconductor chip can be obtained. A plurality of clusters within the circuits on the semiconductor chip can be determined, where a cluster within the plurality of clusters can be synchronized to a cycle boundary. A plurality of counter initializations can be calculated, where the counter initializations can compensate for the cycle count separation across the plurality of clusters. A plurality of counters can be initialized, with a counter from the plurality of counters being associated with each cluster from the plurality of clusters, where the counters from the plurality of counters can be distributed across the plurality of clusters, and where the initializing can be based on the counter initializations that were calculated. Propagation of a global signal proceeds 706. All cell counts of 3 are decremented to 2, so that all cells except the northeastern-most corner cell have a count of 2. Propagation of the global signal proceeds 708. All cell counts of 2 are decremented again, taking the cell count values to 1. Propagation of the global signal proceeds 710. Again, all cell counts are decremented, taking all cell counts from 1 to 0, indicating that the global signal has been propagated across the cluster.

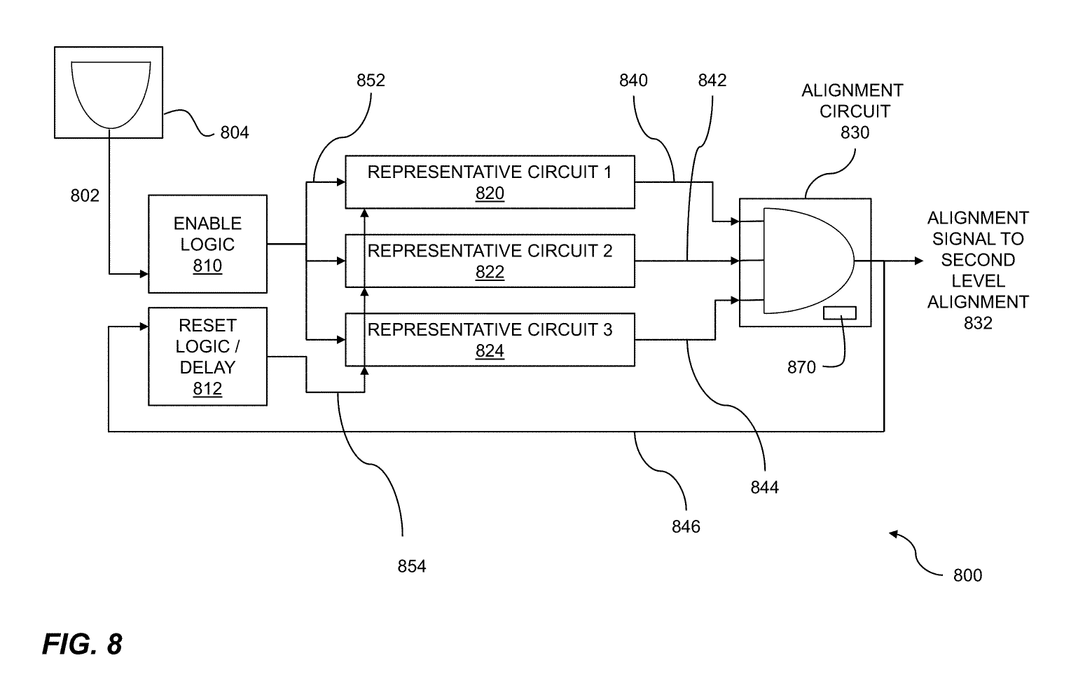

FIG. 8 shows an example block diagram of representative circuits. The diagram 800 shows a first plurality of representative logic circuits, which includes a representative circuit 1 820, a representative circuit 2 822, and a representative circuit 3 824. The representative circuits are copies of functional circuits within a cluster. The plurality of representative logic circuits can comprise ring oscillators. The output 840 of the representative circuit 1 820 feeds into an alignment circuit 830. In embodiments, the alignment circuit 830 includes an AND gate.

The output 842 of the representative circuit 2 822 also feeds into the alignment circuit 830, and the output 844 of the representative circuit 3 824 also feeds into the alignment circuit 830. Note that while three representative circuits are shown in the diagram 800, in practice, more or fewer than three representative circuits can be used. The alignment circuit 830 serves as a first level alignment circuit (first edge aligner). The diagram 800 includes a first edge aligner combining results from the first plurality of representative logic circuits. As each representative circuit (820, 822, and 824) completes its operation, its corresponding output (840, 842, and 844) is asserted. The diagram 800 includes an output from the first edge aligner that becomes active based on a longest delay path from the first plurality of representative logic circuits. Thus, when all outputs are asserted, the output of the alignment circuit 830 is asserted, serving as a first synchronization signal which is provided to the reset logic 812 as a derived signal 846, and is also sent to a second level alignment circuit as an alignment signal 832. In some cases, the derived signal 846 and the alignment signal 832 are the same signal. In other cases, the derived signal 846 can be a delayed version of the alignment signal 832. The alignment signal 832 can be used as a clock type signal for certain types of logic. In some embodiments, the first plurality of representative logic circuits is comprised of self-resetting logic circuitry and there is no specific reset logic 812 external to the representative circuits themselves.

The reset logic 812 can include some delay so that the representative circuits are reset at some period of time after the signal 846 becomes active. In some embodiments, the delay is a separate circuit from the reset logic 812 itself. The diagram 800 includes a first synchronization signal derived from the results from the first plurality of representative logic circuits. The alignment signal 832 of the alignment circuit 830 feeds into the reset logic 812 and also feeds to a second level alignment that is interconnected to multiple clusters, which will be shown further in FIG. 6. The reset logic 812 resets each representative circuit to an initial state via a reset signal 854. The diagram 800 includes a first enablement circuit that enables the first plurality of representative logic circuits (820, 822, and 824). The enable logic 810 receives a signal 802 from the second level alignment circuit to allow the representative circuits to start. The enable logic 810 provides an enable signal 852 to the representative circuit 1 820, the representative circuit 2 822, and the representative circuit 3 824. The signal 802 is asserted when all the interconnected second level alignment circuits indicate completion of respective representative circuits in their respective clusters. In this way, an entire mesh or fabric of clusters can operate synchronously with each other. In embodiments, the signal 802 comes from a combining circuit 804. Since clusters can receive input from multiple second level alignment circuits, the combining circuit 804 can be used to combine inputs from a first second level alignment circuit with inputs from a second level alignment circuit. When both second level alignment signals are asserted, the combining circuit 804 asserts the signal 802 to start the next tic, or cycle, and begin operation of the representative circuits (820, 822, and 824). In some embodiments, the alignment circuit 830 further includes a timing statistics register 870. The timing statistics register 870 can include fields to indicate the number of times each representative circuit was the “critical circuit” for timing, meaning that it was the last representative circuit to complete. The information in the statistics register can be used by chip designers to optimize designs. The timing statistics register 870 can be read and reset by a processor or other test equipment so its results can be accessed and cleared when appropriate.

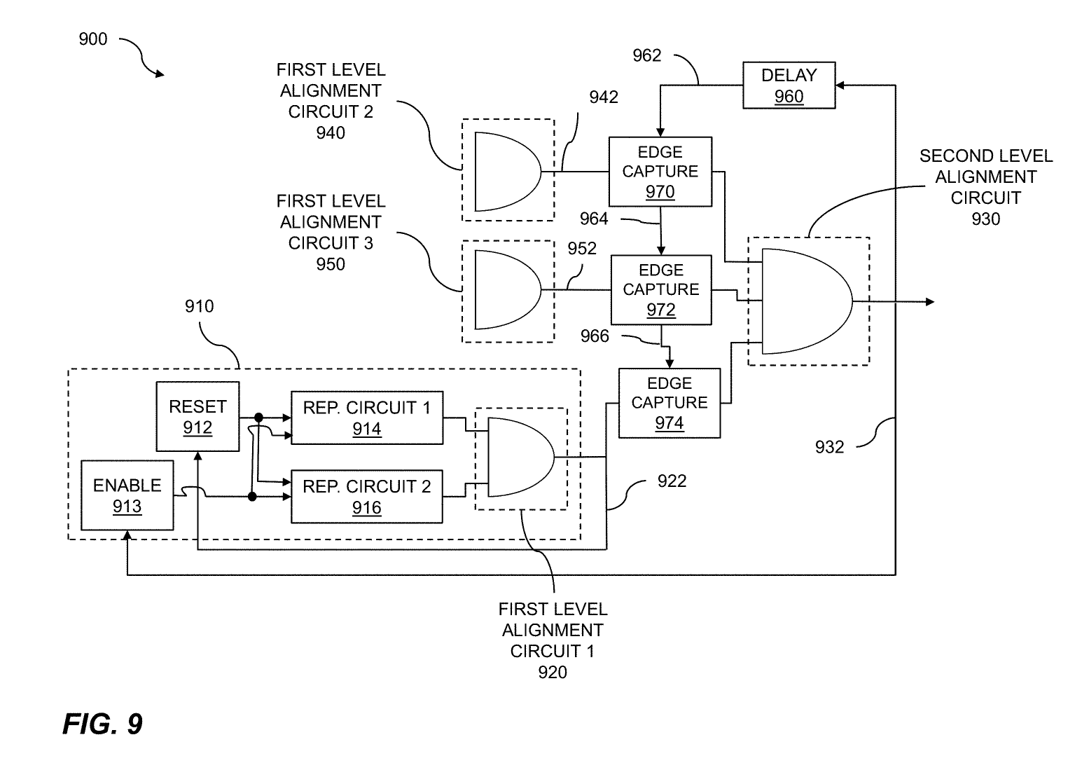

FIG. 9 shows an example schematic of a timing circuit. The schematic 900 shows a first plurality of representative logic circuits which can be selected for their timing characteristics, as previously discussed. The representative logic circuits are indicated as representative circuit 1 914 and representative circuit 2 916. In embodiments, while two representative logic circuits are shown, one or more representative logic circuits are included in the timing circuit. The schematic 900 includes a first level alignment circuit 920 combining results from the first plurality of representative logic circuits. The schematic 900 includes a first enablement circuit 913 that enables the first plurality of representative logic circuits. The schematic 900 includes a first synchronization output signal 922 that can be derived from the results from the first plurality of representative logic circuits.

The schematic 900 includes another first level alignment circuit 940 that combines results from a second plurality of representative logic circuits (not shown). The schematic 900 includes yet another first level alignment circuit 950 combining results from a third plurality of representative logic circuits (not shown). Each first level alignment circuit, or aligner, (920, 940, and 950) can be disposed within a different cluster. An output of each cluster can be captured by edge capture circuits. The schematic 900 includes an edge capture circuit 970 to capture an output signal 942 from the first level alignment circuit 940, an edge capture circuit 972 to capture an output signal 952 from the first level alignment circuit 950, and an edge capture circuit 974 to capture an output signal 922 from the first level alignment circuit 920. The edge capture circuits capture an edge from their respective incoming signals and retain a consistent output until the edge capture circuit is reset. In this manner, the first level alignment signal can be reset but the edge capture circuit output is held active until its value is used by a second level alignment circuit. The edge capture circuit can include a latch, a flip-flop, a storage element, and so on. The edge capture circuit can capture a rising edge of a signal, a falling edge of a signal, a signal transition, etc. The capture circuit can be used to capture a first or other edge of a signal. In embodiments, the outputs from the first level alignment circuits are also used for resetting purposes, self-timing purposes, and so on. In embodiments, the edge capture circuits capture results from the first level alignment circuits and hold the results until the second level alignment circuit can use the results from all of the first level alignment circuits. The output signal 922 of the first level aligner 920 can be configured to activate a reset circuit 912. The reset circuit 912 places each representative circuit (914 and 916) into an initial state. Similarly, the output 942 of the first level alignment circuit 940 can activate a reset circuit within its respective cluster, and the output 952 of the first level alignment circuit 950 can activate a reset circuit within its respective cluster.

Each edge capture circuit can be coupled to a second level alignment circuit 930. The output from the edge capture circuit 974 can be coupled to the second level alignment circuit 930. The output from the edge capture circuit 972 can be coupled to the second level alignment circuit 930. The output from the edge capture circuit 970 can be coupled to the second level alignment circuit 930. While the outputs from three edge capture circuits are shown, in practice one or more outputs from edge capture circuits can be coupled to a second level alignment circuit.

The output of the second level alignment circuit 930 can be a second level synchronization output signal 932 that can trigger the enable circuit 913 of the timing circuit 910. The enable circuit 913 can assert a signal that can allow the representative circuit 914 and the representative circuit 916 to begin operation, starting from the initial state caused by the reset circuit 912. Similarly, the second level synchronization output signal 932 can be connected to an enable circuit like the enable circuit 913 in the other clusters to which it is coupled. Each cluster can include a timing circuit similar to the timing circuit 910. In embodiments, the enable circuit 913 is configured to de-assert after a predetermined time interval, such that the enable signal may de-assert prior to the next tic. In some embodiments, the second level synchronization output signal 932 can be used to generate a reset signal as well for the representative logic circuits. In this situation, the reset circuit 912 is coupled to the second level synchronization output signal 932 rather than the output signal 922 of the first level aligner 920.

The output signal 932 of the second level alignment circuit 930 can be coupled to a delay 960. The delay can be a circuit that can be based on a specific time delay. The output signal 962 of the delay 960 can be configured to activate a reset of the one or more edge capture circuits. As seen in the schematic 900, the signal 962 can reset the edge capture circuits 970, 972, and 974. The output (reset) signal 962 can place each edge capture circuit 970, 972, and 974 into an initial state. In embodiments, the reset output signal 962 is the same as the other reset signals 964 and 966 for the other edge capture latches. The initial states of the edge capture circuits can set up these circuits to capture edges (e.g. rising edges) of signals from the plurality of first level alignment circuits. The second level synchronization output signal 932 can be used as a clock type signal for certain types of logic.

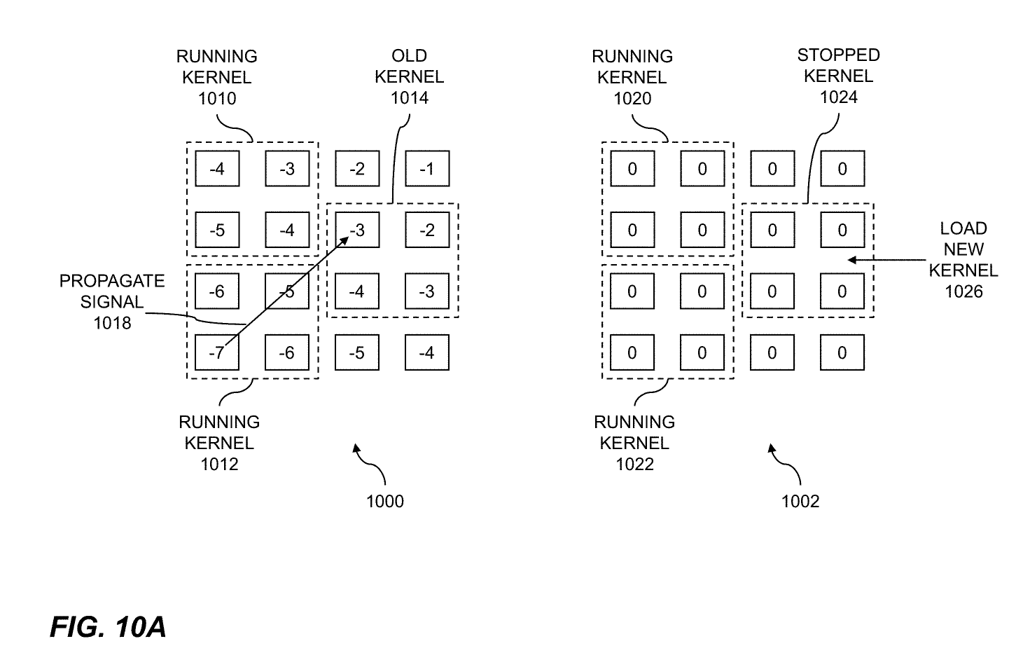

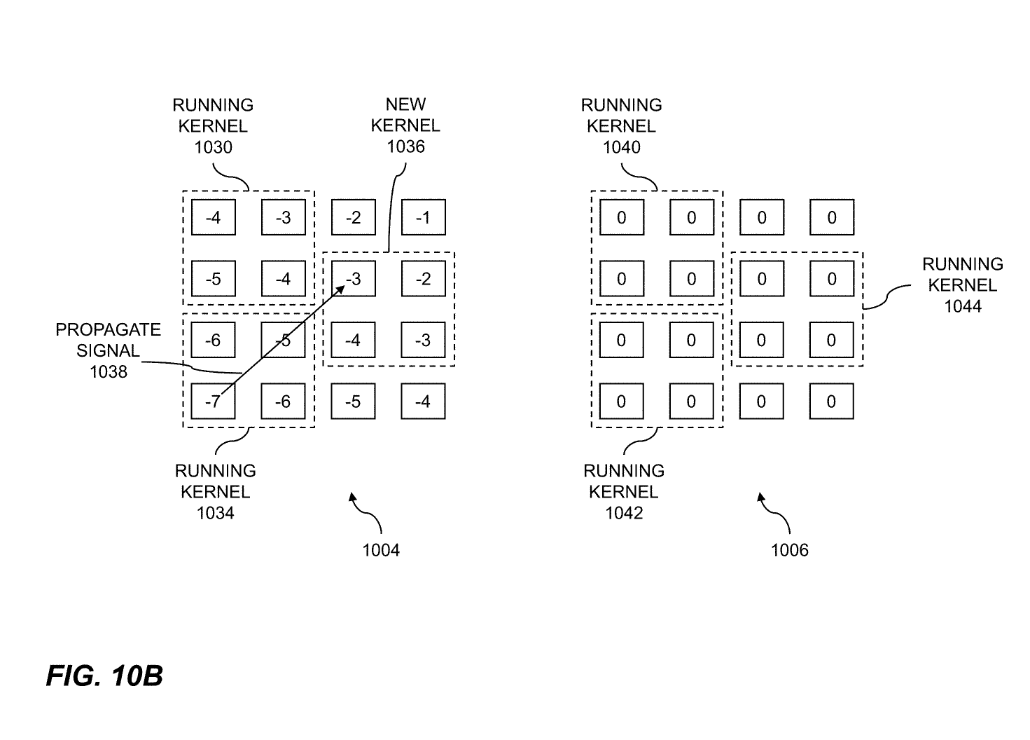

FIG. 10A shows clusters entering configuration mode. Entering configuration mode can be included in the dynamic configuration of a reconfigurable hum fabric. Information can be obtained on logical distances between reconfigurable fabric circuits on a semiconductor chip. A plurality of clusters can be identified within the reconfigurable fabric circuits on the semiconductor chip. A cycle count separation across the plurality of clusters can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters.

The clusters 1000 include a running kernel 1012, a running kernel 1010, and an old kernel 1014 that needs to be replaced or updated. Several currently unused clusters are also shown in the upper right (top row, rightmost two columns) and lower right quadrants (bottom row, rightmost two columns). The clusters are unused in the sense that a kernel is not being executed on them, but they may still be an active part of the reconfigurable fabric by contributing to signal and data propagation, as well as providing storage elements to the fabric. Each cluster within the clusters 1000 shows the current value stored in an up-counter associated with that cluster. In the clusters 1000, the up-counter values range from −1 to −7. The counter values represent each counter being initialized to the sum (minus one plus the Manhattan Distance from end cluster), where the end cluster is chosen to be the uppermost, rightmost cluster and is shown as (−1) in the clusters 1000. A propagate control signal 1018 is sent from a start cluster, the lowermost, leftmost cluster and shown with an up-counter value of (−7), to the end cluster just described for clusters 1000. The signal propagates one cluster per cycle in a Manhattan direction toward the end cluster. The propagate signal 1018 causes each cluster's up-counter to begin incrementing until the up-counters reach zero. A zero up-counter value can indicate that the processors are to be reset, that the processors are to be suspended for configuration, or that the processors are enabled to execute. In configuration mode, the processors included in old kernel 1014 enter configuration mode, while a first running kernel 1012 and a second running kernel 1010 keep running.

The clusters 1002 show the same reconfigurable fabric after configuration mode is entered for old kernel 1014 of clusters 1000, just later in time. A new kernel 1026 is shown loaded into the clusters 1002. Note that a first running kernel 1022 and a second running kernel 1020 of clusters 1002 are the same running kernels as the first running kernel 1012 and the second running kernel 1010 of clusters 1000, respectively. However, the new kernel 1026 is now shown loaded in clusters 1002, and the new kernel is stopped 1024. The new kernel 1026 can be loaded via DMA by the reconfigurable fabric global software. Note that due to the propagate signal 1018, clusters 1002 are all shown with their respective up-counters set to zero.

In embodiments, the reconfigurable fabric can have a low speed scan chain included that can be used to load identification of the clusters to be reprogrammed. In this manner a bit is set within the clusters to be reprogrammed. Then when a sweep propagate signal is applied to the reconfigurable fabric, the program counters are incremented but only those clusters with the reprogramming bit set enter configuration mode. The low speed scan chain can serpentine through the clusters and terminate on one of the clusters. In other embodiments, the low speed scan chain can propagate through clusters and have an output at a boundary of the reconfigurable fabric. In some embodiments, multiple low speed scan chains can be utilized for setting the program identification bits. A sweep propagate signal from a corner of the reconfigurable fabric causes the propagate signal 1018 to impact the reconfigurable fabric. In the same manner the identification bits can be set to cause a subset of the clusters to exit the configuration mode at the next firing of the sweep propagate signal.

FIG. 10B shows clusters exiting configuration mode. Exiting configuration mode can be included in the dynamic configuration of a reconfigurable hum fabric. Information can be obtained on logical distances between reconfigurable fabric circuits on a semiconductor chip. A plurality of clusters can be identified within the reconfigurable fabric circuits on the semiconductor chip. A cycle count separation across the plurality of cluster can be evaluated using information on the logical distances. A plurality of counter initializations can be calculated where the counter initializations compensate for the cycle count separation across the clusters. A plurality of counters can be initialized, with a counter from the plurality of counters being associated with each cluster from the plurality of clusters, where the counters are distributed across the clusters, and where the initializing is based on the counter initializations that were calculated. The plurality of counters can be started to coordinate configuration across the plurality of clusters.

The clusters 1004 are the same clusters as shown in FIG. 10A, just later in time. The clusters 1004 include running kernel 1034, running kernel 1030, and new kernel 1036. Several currently unused clusters are also shown in the upper right (top row, rightmost two columns) and lower right quadrants (bottom row, rightmost two columns). The clusters are unused in the sense that a kernel is not being executed on them, but they may still be an active part of the reconfigurable fabric by contributing to signal and data propagation, as well as providing storage elements to the fabric. Each cluster within the clusters 1004 shows the new value stored in an up-counter associated with that cluster. In the clusters 1004, the up-counter values range from −1 to −7. The counter values represent each counter being initialized to the sum (one plus the Manhattan Distance from end cluster), where the end cluster is chosen to be the uppermost, rightmost cluster and is shown as (−1) in the clusters 1004. Again, clusters 1004 are the same clusters as clusters 1000, just later in time. A propagate control signal 1038 is sent from the start cluster, the lowermost, leftmost cluster and shown with an up-counter value of (−7), to the end cluster described above for clusters 1000. The signal propagates one cluster per cycle in a Manhattan direction toward the end cluster. The propagate signal 1038 enables each cluster's up-counter to begin incrementing until the up-counters reach zero. A zero up-counter value for clusters 1004 indicates that the processors are enabled to exit configuration mode and fully enter running mode. Exiting configuration mode enables the new kernel 1036 to begin execution upon each cluster's up-counter reaching zero, thus synchronizing the start (restart) of all of the clusters 1004 of the reconfigurable fabric. Of course, the reconfigurable fabric implementation may include many more clusters than shown in clusters 1000, 1002, 1004, or 1006.

The clusters 1006 show the same reconfigurable fabric after configuration mode is exited and all of the kernels 1042, 1040, and 1044 are running. Note that running kernel 1042 and running kernel 1040 of clusters 1006 are the same running kernels as running kernel 1034 and running kernel 1030 of clusters 1004, respectively. New kernel 1044 is now shown running in clusters 1006.

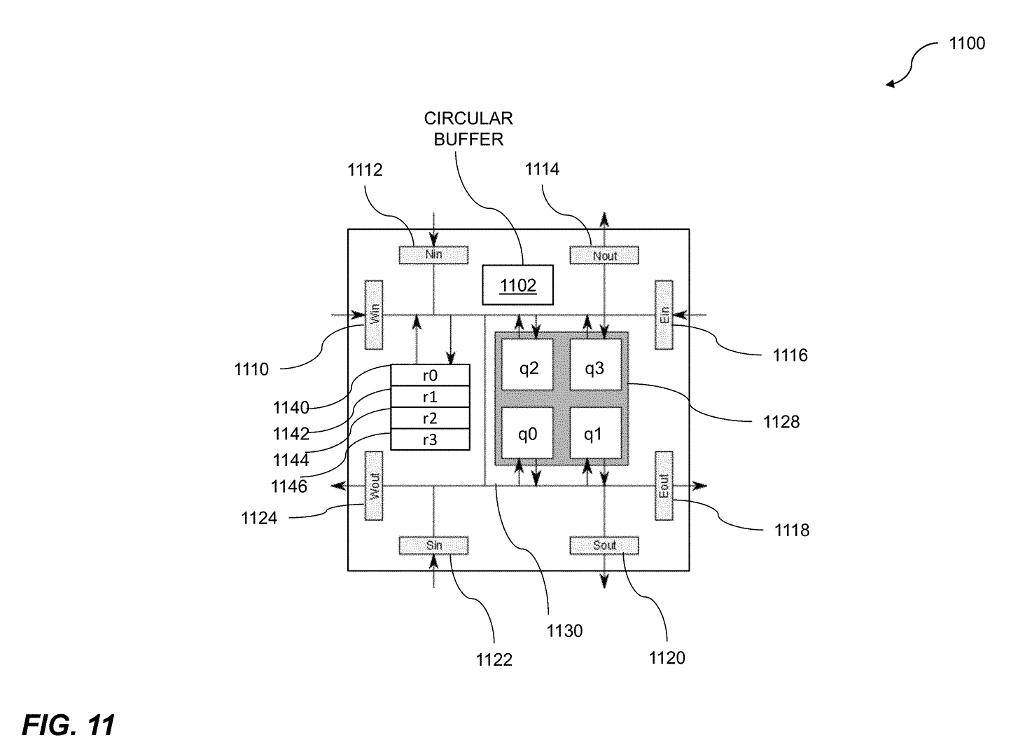

FIG. 11 shows a cluster for coarse-grained reconfigurable processing. The cluster for coarse-grained reconfigurable processing 1100 can be used for dynamic reconfiguration using data transfer control. The dynamic reconfiguration can include accessing clusters on a reconfigurable fabric to implement a logical or other operation. The clusters on the reconfigurable fabric can include processing elements, switching elements, storage elements, etc. Clusters can be provisioned for a first agent, where the clusters that are provisioned include a first data transfer control block. Additional clusters can be provisioned for a second agent, where the second agent can include a second data transfer control block. The logical operation can be performed using the first agent, and control information can be transferred from the first data transfer control block to the second data transfer control block.

The cluster 1100 comprises a circular buffer 1102. The circular buffer 1102 can be referred to as a main circular buffer or a switch-instruction circular buffer. In some embodiments, the cluster 1100 comprises additional circular buffers corresponding to processing elements within the cluster. The additional circular buffers can be referred to as processor instruction circular buffers. The example cluster 1100 comprises a plurality of logical elements, configurable connections between the logical elements, and a circular buffer 1102 controlling the configurable connections. The logical elements can further comprise one or more of switching elements, processing elements, or storage elements. The example cluster 1100 also comprises four processing elements—q0, q1, q2, and q3. The four processing elements can collectively be referred to as a “quad,” and can be jointly indicated by a grey reference box 1128. In embodiments, there is intercommunication among and between each of the four processing elements. In embodiments, the circular buffer 1102 controls the passing of data to the quad of processing elements 1128 through switching elements. In embodiments, the four processing elements 1128 comprise a processing cluster. In some cases, the processing elements can be placed into a sleep state. In embodiments, the processing elements wake up from a sleep state when valid data is applied to the inputs of the processing elements. In embodiments, the individual processors of a processing cluster share data and/or instruction caches. The individual processors of a processing cluster can implement message transfer via a bus or shared memory interface. Power gating can be applied to one or more processors (e.g. q1) in order to reduce power.

The cluster 1100 can further comprise storage elements coupled to the configurable connections. As shown, the cluster 1100 comprises four storage elements—r0 1140, r1 1142, r2 1144, and r3 1146. The cluster 1100 further comprises a north input (Nin) 1112, a north output (Nout) 1114, an east input (Ein) 1116, an east output (Eout) 1118, a south input (Sin) 1122, a south output (Sout) 1120, a west input (Win) 1110, and a west output (Wout) 1124. The circular buffer 1102 can contain switch instructions that implement configurable connections. For example, an instruction effectively connects the west input 1110 with the north output 1114 and the east output 1118 and this routing is accomplished via bus 1130. The cluster 1100 can further comprise a plurality of circular buffers residing on a semiconductor chip where the plurality of circular buffers controls unique, configurable connections between the logical elements. The storage elements can include instruction random access memory (I-RAM) and data random access memory (D-RAM). The I-RAM and the D-RAM can be quad I-RAM and quad D-RAM, respectively, where the I-RAM and/or the D-RAM supply instructions and/or data, respectively, to the processing quad of a switching element.

A preprocessor or compiler can be configured to prevent data collisions within the circular buffer 1102. The prevention of collisions can be accomplished by inserting no-op or sleep instructions into the circular buffer (pipeline). Alternatively, in order to prevent a collision on an output port, intermediate data can be stored in registers for one or more pipeline cycles before being sent out on the output port. In other situations, the preprocessor can change one switching instruction to another switching instruction to avoid a conflict. For example, in some instances the preprocessor can change an instruction placing data on the west output 1124 to an instruction placing data on the south output 1120, such that the data can be output on both output ports within the same pipeline cycle. In a case where data needs to travel to a cluster that is both south and west of the cluster 1100, it can be more efficient to send the data directly to the south output port rather than to store the data in a register first, and then send the data to the west output on a subsequent pipeline cycle.

An L2 switch interacts with the instruction set. A switch instruction typically has both a source and a destination. Data is accepted from the source and sent to the destination. There are several sources (e.g. any of the quads within a cluster, any of the L2 directions—North, East, South, West, a switch register, one of the quad RAMs—data RAM, IRAM, PE/Co Processor Register). As an example, to accept data from any L2 direction, a “valid” bit is used to inform the switch that the data flowing through the fabric is indeed valid. The switch will select the valid data from the set of specified inputs. For this to function properly, only one input can have valid data, and the other inputs must all be marked as invalid. It should be noted that this fan-in operation at the switch inputs operates independently for control and data. There is no requirement for a fan-in mux to select data and control bits from the same input source. Data valid bits are used to select valid data, and control valid bits are used to select the valid control input. There are many sources and destinations for the switching element, which can result in too many instruction combinations, so the L2 switch has a fan-in function enabling input data to arrive from one and only one input source. The valid input sources are specified by the instruction. Switch instructions are therefore formed by combining a number of fan-in operations and sending the result to a number of specified switch outputs.

In the event of a software error, multiple valid bits may arrive at an input. In this case, the hardware implementation can perform any safe function of the two inputs. For example, the fan-in could implement a logical OR of the input data. Any output data is acceptable because the input condition is an error, so long as no damage is done to the silicon. In the event that a bit is set to ‘1’ for both inputs, an output bit should also be set to ‘1’. A switch instruction can accept data from any quad or from any neighboring L2 switch. A switch instruction can also accept data from a register or a microDMA controller. If the input is from a register, the register number is specified. Fan-in may not be supported for many registers as only one register can be read in a given cycle. If the input is from a microDMA controller, a DMA protocol is used for addressing the resource.

For many applications, the reconfigurable fabric can be a DMA slave, which enables a host processor to gain direct access to the instruction and data RAMs (and registers) that are located within the quads in the cluster. DMA transfers are initiated by the host processor on a system bus. Several DMA paths can propagate through the fabric in parallel. The DMA paths generally start or finish at a streaming interface to the processor system bus. DMA paths may be horizontal, vertical, or a combination (as determined by a router). To facilitate high bandwidth DMA transfers, several DMA paths can enter the fabric at different times, providing both spatial and temporal multiplexing of DMA channels. Some DMA transfers can be initiated within the fabric, enabling DMA transfers between the block RAMs without external supervision. It is possible for a cluster “A”, to initiate a transfer of data between cluster “B” and cluster “C” without any involvement of the processing elements in clusters “B” and “C”. Furthermore, cluster “A” can initiate a fan-out transfer of data from cluster “B” to clusters “C”, “D”, and so on, where each destination cluster writes a copy of the DMA data to different locations within their Quad RAMs. A DMA mechanism may also be used for programming instructions into the instruction RAMs.

Accesses to RAM in different clusters can travel through the same DMA path, but the transactions must be separately defined. A maximum block size for a single DMA transfer can be 8 KB. Accesses to data RAMs can be performed either when the processors are running, or while the processors are in a low power “sleep” state. Accesses to the instruction RAMs and the PE and Co-Processor Registers may be performed during configuration mode. The quad RAMs may have a single read/write port with a single address decoder, thus allowing shared access by the quads and the switches. The static scheduler (i.e. the router) determines when a switch is granted access to the RAMs in the cluster. The paths for DMA transfers are formed by the router by placing special DMA instructions into the switches and determining when the switches can access the data RAMs. A microDMA controller within each L2 switch is used to complete data transfers. DMA controller parameters can be programmed using a simple protocol that forms the “header” of each access.

In embodiments, the computations that can be performed on a cluster for coarse-grained reconfigurable processing can be represented by a data flow graph. Dataflow processors, dataflow processor elements, and the like, are particularly well suited to processing the various nodes of data flow graphs. The data flow graphs can represent communications between and among agents, matrix computations, tensor manipulations, Boolean functions, and so on. Dataflow processors can be applied to many applications where large amounts of data such as unstructured data are processed. Typical processing applications for unstructured data can include speech and image recognition, natural language processing, bioinformatics, customer relationship management, digital signal processing (DSP), graphics processing (GP), network routing, telemetry such as weather data, data warehousing, and so on. Dataflow processors can be programmed using software and can be applied to highly advanced problems in computer science such as deep learning. Deep learning techniques can include an artificial neural network, a convolutional neural network, etc. These success of these techniques is highly dependent on large quantities of data for training and learning. The data-driven nature of these techniques is well suited to implementations based on dataflow processors. The dataflow processor can receive a data flow graph such as an acyclic data flow graph, where the data flow graph can represent a deep learning network. The data flow graph can be assembled at runtime, where assembly can include input/output, memory input/output, and so on. The assembled data flow graph can be executed on the dataflow processor.

The dataflow processors can be organized in a variety of configurations. One configuration can include processing element quads with arithmetic units. A dataflow processor can include one or more processing elements (PE). The processing elements can include a processor, a data memory, an instruction memory, communications capabilities, and so on. Multiple PEs can be grouped, where the groups can include pairs, quads, octets, etc. The PEs arranged in configurations such as quads can be coupled to arithmetic units, where the arithmetic units can be coupled to or included in data processing units (DPU). The DPUs can be shared between and among quads. The DPUs can provide arithmetic techniques to the PEs, communications between quads, and so on.

The dataflow processors, including dataflow processors arranged in quads, can be loaded with kernels. The kernels can be included in a data flow graph, for example. In order for the dataflow processors to operate correctly, the quads can require reset and configuration modes. Processing elements can be configured into clusters of PEs. Kernels can be loaded onto PEs in the cluster, where the loading of kernels can be based on availability of free PEs, an amount of time to load the kernel, an amount of time to execute the kernel, and so on. Reset can begin with initializing up-counters coupled to PEs in a cluster of PEs. Each up-counter is initialized with a value of minus one plus the Manhattan distance from a given PE in a cluster to the end of the cluster. A Manhattan distance can include a number of steps to the east, west, north, and south. A control signal can be propagated from the start cluster to the end cluster. The control signal advances one cluster per cycle. When the counters for the PEs all reach 0 then the processors have been reset. The processors can be suspended for configuration, where configuration can include loading of one or more kernels onto the cluster. The processors can be enabled to execute the one or more kernels. Configuring mode for a cluster can include propagating a signal. Clusters can be preprogrammed to enter configuration mode. Various techniques, including direct memory access (DMA) can be used to load instructions from the kernel into instruction memories of the PEs. The clusters that were pre-programmed to enter configuration mode can also be pre-programmed to exit configuration mode. When configuration mode has been exited, execution of the one or more kernels loaded onto the clusters can commence.

Dataflow processes that can be executed by dataflow processors can be managed by a software stack. A software stack can include a set of subsystems, including software subsystems, which may be needed to create a software platform. The software platform can include a complete software platform. A complete software platform can include a set of software subsystems required to support one or more applications. A software stack can include both offline operations and online operations. Offline operations can include software subsystems such as compilers, linkers, simulators, emulators, and so on. The offline software subsystems can be included in a software development kit (SDK). The online operations can include dataflow partitioning, data flow graph throughput optimization, and so on. The online operations can be executed on a session host and can control a session manager. Online operations can include resource management, monitors, drivers, etc. The online operations can be executed on an execution engine. The online operations can include a variety of tools which can be stored in an agent library. The tools can include BLAS™, CONV2D™, SoftMax™, and so on.

Software to be executed on a dataflow processor can include precompiled software or agent generation. The pre-compiled agents can be stored in an agent library. An agent library can include one or more computational models which can simulate actions and interactions of autonomous agents. Autonomous agents can include entities such as groups, organizations, and so on. The actions and interactions of the autonomous agents can be simulated to determine how the agents can influence operation of a whole system. Agent source code can be provided from a variety of sources. The agent source code can be provided by a first entity, provided by a second entity, and so on. The source code can be updated by a user, downloaded from the Internet, etc. The agent source code can be processed by a software development kit, where the software development kit can include compilers, linkers, assemblers, simulators, debuggers, and so on. The agent source code that can be operated on by the software development kit (SDK) can be located in an agent library. The agent source code can be created using a variety of tools, where the tools can include MATMUL™, Batchnorm™, Relu™, and so on. The agent source code that has been operated on can include functions, algorithms, heuristics, etc., that can be used to implement a deep learning system.

A software development kit can be used to generate code for the dataflow processor or processors. The software development kit (SDK) can include a variety of tools which can be used to support a deep learning technique or other technique which requires processing of large amounts of data such as unstructured data. The SDK can support multiple machine learning techniques such as those based on GAMMTm, sigmoid, and so on. The SDK can include a low-level virtual machine (LLVM) which can serve as a front end to the SDK. The SDK can include a simulator. The SDK can include a Boolean satisfiability solver (SAT solver). The SAT solver can include a compiler, a linker, and so on. The SDK can include an architectural simulator, where the architectural simulator can simulate a dataflow processor or processors. The SDK can include an assembler, where the assembler can be used to generate object modules. The object modules can represent agents. The agents can be stored in a library of agents. Other tools can be included in the SDK. The various techniques of the SDK can operate on various representations of a wave flow graph (WFG).

A reconfigurable fabric can include quads of elements. The elements of the reconfigurable fabric can include processing elements, switching elements, storage elements, and so on. An element such as a storage element can be controlled by a rotating circular buffer. In embodiments, the rotating circular buffer can be statically scheduled. The data operated on by the agents that are resident within the reconfigurable buffer can include tensors. Tensors can include one or more blocks. The reconfigurable fabric can be configured to process tensors, tensor blocks, tensors and blocks, etc. One technique for processing tensors includes deploying agents in a pipeline. That is, the output of one agent can be directed to the input of another agent. Agents can be assigned to clusters of quads, where the clusters can include one or more quads. Multiple agents can be pipelined when there are sufficient clusters of quads to which the agents can be assigned. Multiple pipelines can be deployed. Pipelining of the multiple agents can reduce the sizes of input buffers, output buffers, intermediate buffers, and other storage elements. Pipelining can further reduce memory bandwidth needs of the reconfigurable fabric.

Agents can be used to support dynamic reconfiguration of the reconfigurable fabric. The agents that support dynamic reconfiguration of the reconfigurable fabric can include interface signals in a control unit. The interface signals can include suspend, agent inputs empty, agent outputs empty, and so on. The suspend signal can be implemented using a variety of techniques such as a semaphore, a streaming input control signal, and the like. When a semaphore is used, the agent that is controlled by the semaphore can monitor the semaphore. In embodiments, a direct memory access (DMA) controller can wake the agent when the setting of the semaphore has been completed. The streaming control signal, if used, can wake a control unit if the control unit is sleeping. A response received from the agent can be configured to interrupt the host software.

The suspend semaphore can be asserted by runtime software in advance of commencing dynamic reconfiguration of the reconfigurable fabric. Upon detection of the semaphore, the agent can begin preparing for entry into a partially resident state. A partially resident state for the agent can include having the agent control unit resident after the agent kernel is removed. The agent can complete processing of any currently active tensor being operated on by the agent. In embodiments, a done signal and a fire signal may be sent to upstream or downstream agents, respectively. A done signal can be sent to the upstream agent to indicate that all data has been removed from its output buffer. A fire signal can be sent to a downstream agent to indicate that data in the output buffer is ready for processing by the downstream agent. The agent can continue to process incoming done signals and fire signals but will not commence processing of any new tensor data after completion of the current tensor processing by the agent. The semaphore can be reset by the agent to indicate to a host that the agent is ready to be placed into partial residency. In embodiments, having the agent control unit resident after the agent kernel is removed comprises having the agent partially resident. A control unit may not assert one or more signals, nor expect one or more responses from a kernel in the agent, when a semaphore has been reset.

Other signals from an agent can be received by a host. The signals can include an agent inputs empty signal, an agent outputs empty signal, and so on. The agent inputs empty signal can be sent from the agent to the host and can indicate that the input buffers are empty. The agent inputs empty signal can only be sent from the agent when the agent is partially resident. The agent outputs empty signal can be sent from the agent to the host and can indicate that the output buffers are empty. The agent outputs empty can only be sent from the agent to the host when the agent is partially resident. When the runtime (host) software receives both signals, agent inputs empty and agent outputs empty, from the partially resident agent, the agent can be swapped out of the reconfigurable fabric and can become fully vacant.

Recall that an agent can be one of a plurality of agents that form a data flow graph. The data flow graph can be based on a plurality of subgraphs. The data flow graph can be based on agents which can support three states of residency: fully resident, partially resident, and fully vacant. A complete subsection (or subgraph) based on the agents that support the three states of residency can be swapped out of the reconfigurable fabric. The swapping out of the subsection can be based on asserting a suspend signal input to an upstream agent. The asserting of the suspend signal can be determined by the runtime software. When a suspend signal is asserted, the agent can stop consuming input data such as an input sensor. The tensor can queue within the input buffers of the agent. The agent kernel can be swapped out of the reconfigurable fabric, leaving the agent partially resident while the agent waits for the downstream agents to drain the output buffers for the agent. When an upstream agent is fully resident, the agent may not be able to fully vacant because a fire signal might be sent to the agent by the upstream agent. When the upstream agent is partially resident or is fully vacant, then the agent can be fully vacated from the reconfigurable fabric. The agent can be fully vacated if it asserts both the input buffers empty and output buffers empty signals.

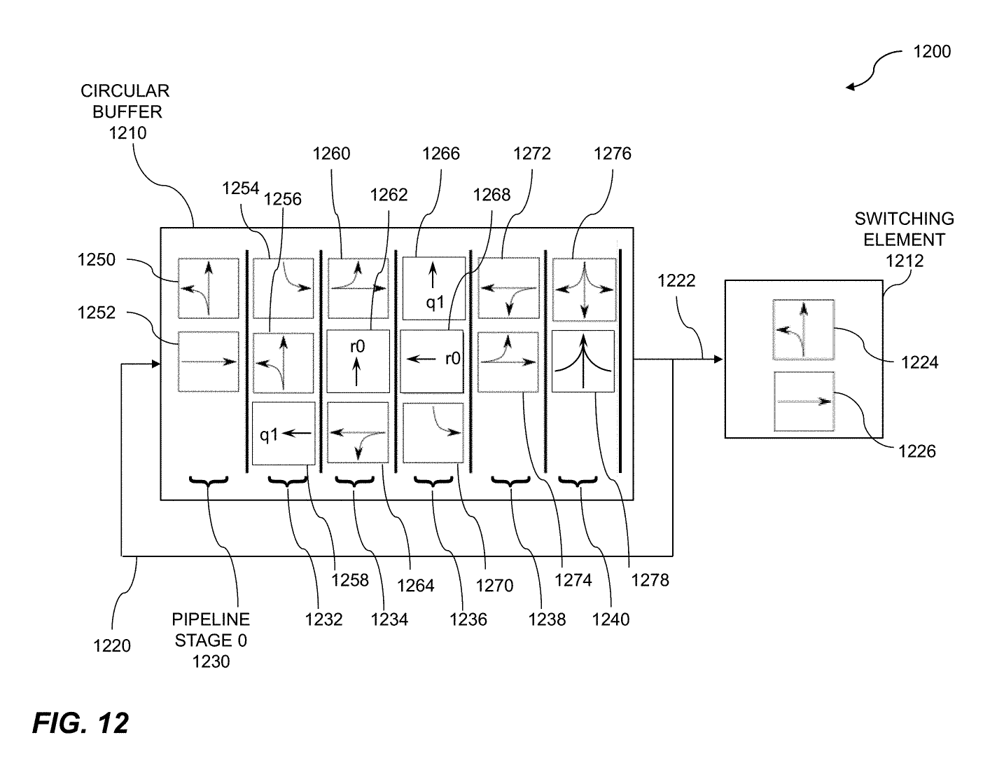

FIG. 12 shows a block diagram of a circular buffer. The circular buffer 1200 can include a switching element 1212 corresponding to the circular buffer. The circular buffer and the corresponding switching element can be used in part for dynamic reconfiguration using data transfer control. Using the circular buffer 1210 and the corresponding switching element 1212, data can be obtained from a first switching unit, where the first switching unit can be controlled by a first circular buffer. Data can be sent to a second switching element, where the second switching element can be controlled by a second circular buffer. The obtaining data from the first switching element and the sending data to the second switching element can include a direct memory access (DMA). The circular buffer block diagram 1200 describes a processor-implemented method for data manipulation. The circular buffer 1210 contains a plurality of pipeline stages. Each pipeline stage contains one or more instructions, up to a maximum instruction depth. In the embodiment shown in FIG. 12, the circular buffer 1210 is a 6×3 circular buffer, meaning that it implements a six-stage pipeline with an instruction depth of up to three instructions per stage (column). Hence, the circular buffer 1210 can include one, two, or three switch instruction entries per column. In some embodiments, the plurality of switch instructions per cycle can comprise two or three switch instructions per cycle. However, in certain embodiments, the circular buffer 1210 supports only a single switch instruction in a given cycle. In the circular buffer block diagram 1200 shown, Pipeline Stage 0 1230 has an instruction depth of two instructions 1250 and 1252. Though the remaining pipeline stages 1-5 are not textually labeled in the FIG. 1200, the stages are indicated by callouts 1232, 1234, 1236, 1238 and 1240. Pipeline stage 1 1232 has an instruction depth of three instructions 1254, 1256, and 1258. Pipeline stage 2 1234 has an instruction depth of three instructions 1260, 1262, and 1264. Pipeline stage 3 1236 also has an instruction depth of three instructions 1266, 1268, and 1270. Pipeline stage 4 1238 has an instruction depth of two instructions 1272 and 1274. Pipeline stage 5 1240 has an instruction depth of two instructions 1276 and 1278. In embodiments, the circular buffer 1210 includes 64 columns. During operation, the circular buffer 1210 rotates through configuration instructions. The circular buffer 1210 can dynamically change operation of the logical elements based on the rotation of the circular buffer. The circular buffer 1210 can comprise a plurality of switch instructions per cycle for the configurable connections.

The instruction 1252 is an example of a switch instruction. In embodiments, each cluster has four inputs and four outputs, each designated within the cluster's nomenclature as “north,” “east,” “south,” and “west” respectively. For example, the instruction 1252 in the diagram 1200 is a west-to-east transfer instruction. The instruction 1252 directs the cluster to take data on its west input and send out the data on its east output. In another example of data routing, the instruction 1250 is a fan-out instruction. The instruction 1250 instructs the cluster to take data from its south input and send out on the data through both its north output and its west output. The arrows within each instruction box indicate the source and destination of the data. The instruction 1278 is an example of a fan-in instruction. The instruction 1278 takes data from the west, south, and east inputs and sends out the data on the north output. Therefore, the configurable connections can be considered to be time multiplexed.

In embodiments, the clusters implement multiple storage elements in the form of registers. In the example 1200 shown, the instruction 1262 is a local storage instruction. The instruction 1262 takes data from the instruction's south input and stores it in a register (r0). Another instruction (not shown) is a retrieval instruction. The retrieval instruction takes data from a register (e.g. r0) and outputs it from the instruction's output (north, south, east, west). Some embodiments utilize four general purpose registers, referred to as registers r0, r1, r2, and r3. The registers are, in embodiments, storage elements which store data while the configurable connections are busy with other data. In embodiments, the storage elements are 32-bit registers. In other embodiments, the storage elements are 64-bit registers. Other register widths are possible.

The obtaining data from a first switching element and the sending the data to a second switching element can include a direct memory access (DMA). A DMA transfer can continue while valid data is available for the transfer. A DMA transfer can terminate when it has completed without error, or when an error occurs during operation. Typically, a cluster that initiates a DMA transfer will request to be brought out of sleep state when the transfer is completed. This waking is achieved by setting control signals that can control the one or more switching elements. Once the DMA transfer is initiated with a start instruction, a processing element or switching element in the cluster can execute a sleep instruction to place itself to sleep. When the DMA transfer terminates, the processing elements and/or switching elements in the cluster can be brought out of sleep after the final instruction is executed. Note that if a control bit can be set in the register of the cluster that is operating as a slave in the transfer, that cluster can also be brought out of sleep state if it is asleep during the transfer.

The cluster that is involved in a DMA and can be brought out of sleep after the DMA terminates can determine that it has been brought out of a sleep state based on the code that is executed. A cluster can be brought out of a sleep state based on the arrival of a reset signal and the execution of a reset instruction. The cluster can be brought out of sleep by the arrival of valid data (or control) following the execution of a switch instruction. A processing element or switching element can determine why it was brought out of a sleep state by the context of the code that the element starts to execute. A cluster can be awoken during a DMA operation by the arrival of valid data. The DMA instruction can be executed while the cluster remains asleep as the cluster awaits the arrival of valid data. Upon arrival of the valid data, the cluster is woken and the data stored. Accesses to one or more data random access memories (RAM) can be performed when the processing elements and the switching elements are operating. The accesses to the data RAMs can also be performed while the processing elements and/or switching elements are in a low power sleep state.

In embodiments, the clusters implement multiple processing elements in the form of processor cores, referred to as cores q0, q1, q2, and q3. In embodiments, four cores are used, though any number of cores can be implemented. The instruction 1258 is a processing instruction. The instruction 1258 takes data from the instruction's east input and sends it to a processor q1 for processing. The processors can perform logic operations on the data, including, but not limited to, a shift operation, a logical AND operation, a logical OR operation, a logical NOR operation, a logical XOR operation, an addition, a subtraction, a multiplication, and a division. Thus, the configurable connections can comprise one or more of a fan-in, a fan-out, and a local storage.

In the example 1200 shown, the circular buffer 1210 rotates instructions in each pipeline stage into switching element 1212 via a forward data path 1222, and also back to a pipeline stage 0 1230 via a feedback data path 1220. Instructions can include switching instructions, storage instructions, and processing instructions, among others. The feedback data path 1220 can allow instructions within the switching element 1212 to be transferred back to the circular buffer. Hence, the instructions 1224 and 1226 in the switching element 1212 can also be transferred back to pipeline stage 0 as the instructions 1250 and 1252. In addition to the instructions depicted on FIG. 12, a no-op instruction can also be inserted into a pipeline stage. In embodiments, a no-op instruction causes execution to not be performed for a given cycle. In effect, the introduction of a no-op instruction can cause a column within the circular buffer 1210 to be skipped in a cycle. In contrast, not skipping an operation indicates that a valid instruction is being pointed to in the circular buffer. A sleep state can be accomplished by not applying a clock to a circuit, performing no processing within a processor, removing a power supply voltage or bringing a power supply to ground, storing information into a non-volatile memory for future use and then removing power applied to the memory, or by similar techniques. A sleep instruction that causes no execution to be performed until a predetermined event occurs which causes the logical element to exit the sleep state can also be explicitly specified. The predetermined event can be the arrival or availability of valid data. The data can be determined to be valid using null convention logic (NCL). In embodiments, only valid data can flow through the switching elements and invalid data points (Xs) are not propagated by instructions.

In some embodiments, the sleep state is exited based on an instruction applied to a switching fabric. The sleep state can, in some embodiments, only be exited by a stimulus external to the logical element and not based on the programming of the logical element. The external stimulus can include an input signal, which in turn can cause a wake up or an interrupt service request to execute on one or more of the logical elements. An example of such a wake-up request can be seen in the instruction 1258, assuming that the processor q1 was previously in a sleep state. In embodiments, when the instruction 1258 takes valid data from the east input and applies that data to the processor q1, the processor q1 wakes up and operates on the received data. In the event that the data is not valid, the processor q1 can remain in a sleep state. At a later time, data can be retrieved from the q1 processor, e.g. by using an instruction such as the instruction 1266. In the case of the instruction 1266, data from the processor q1 is moved to the north output. In some embodiments, if Xs have been placed into the processor q1, such as during the instruction 1258, then Xs would be retrieved from the processor q1 during the execution of the instruction 1266 and applied to the north output of the instruction 1266.

A collision occurs if multiple instructions route data to a particular port in a given pipeline stage. For example, if instructions 1252 and 1254 are in the same pipeline stage, they will both send data to the east output at the same time, thus causing a collision since neither instruction is part of a time-multiplexed fan-in instruction (such as the instruction 1278). To avoid potential collisions, certain embodiments use preprocessing, such as by a compiler, to arrange the instructions in such a way that there are no collisions when the instructions are loaded into the circular buffer. Thus, the circular buffer 1210 can be statically scheduled in order to prevent data collisions. Thus, in embodiments, the circular buffers are statically scheduled. In embodiments, when the preprocessor detects a data collision, the scheduler changes the order of the instructions to prevent the collision. Alternatively, or additionally, the preprocessor can insert further instructions such as storage instructions (e.g. the instruction 1262), sleep instructions, or no-op instructions, to prevent the collision. Alternatively, or additionally, the preprocessor can replace multiple instructions with a single fan-in instruction. For example, if a first instruction sends data from the south input to the north output and a second instruction sends data from the west input to the north output in the same pipeline stage, the first and second instruction can be replaced with a fan-in instruction that routes the data from both of those inputs to the north output in a deterministic way to avoid a data collision. In this case, the machine can guarantee that valid data is only applied on one of the inputs for the fan-in instruction.

Returning to DMA, a channel configured as a DMA channel requires a flow control mechanism that is different from regular data channels. A DMA controller can be included in interfaces to master DMA transfer through the processing elements and switching elements. For example, if a read request is made to a channel configured as DMA, the Read transfer is mastered by the DMA controller in the interface. It includes a credit count that keeps track of the number of records in a transmit (Tx) FIFO that are known to be available. The credit count is initialized based on the size of the Tx FIFO. When a data record is removed from the Tx FIFO, the credit count is increased. If the credit count is positive, and the DMA transfer is not complete, an empty data record can be inserted into a receive (Rx) FIFO. The memory bit is set to indicate that the data record should be populated with data by the source cluster. If the credit count is zero (meaning the Tx FIFO is full), no records are entered into the Rx FIFO. The FIFO to fabric block will make sure the memory bit is reset to 0 which thereby prevents a microDMA controller in the source cluster from sending more data.

Each slave interface manages four interfaces between the FIFOs and the fabric. Each interface can contain up to 15 data channels. Therefore, a slave should manage read/write queues for up to 60 channels. Each channel can be programmed to be a DMA channel, or a streaming data channel. DMA channels are managed using a DMA protocol. Streaming data channels are expected to maintain their own form of flow control using the status of the Rx FIFOs (obtained using a query mechanism). Read requests to slave interfaces use one of the flow control mechanisms described previously.

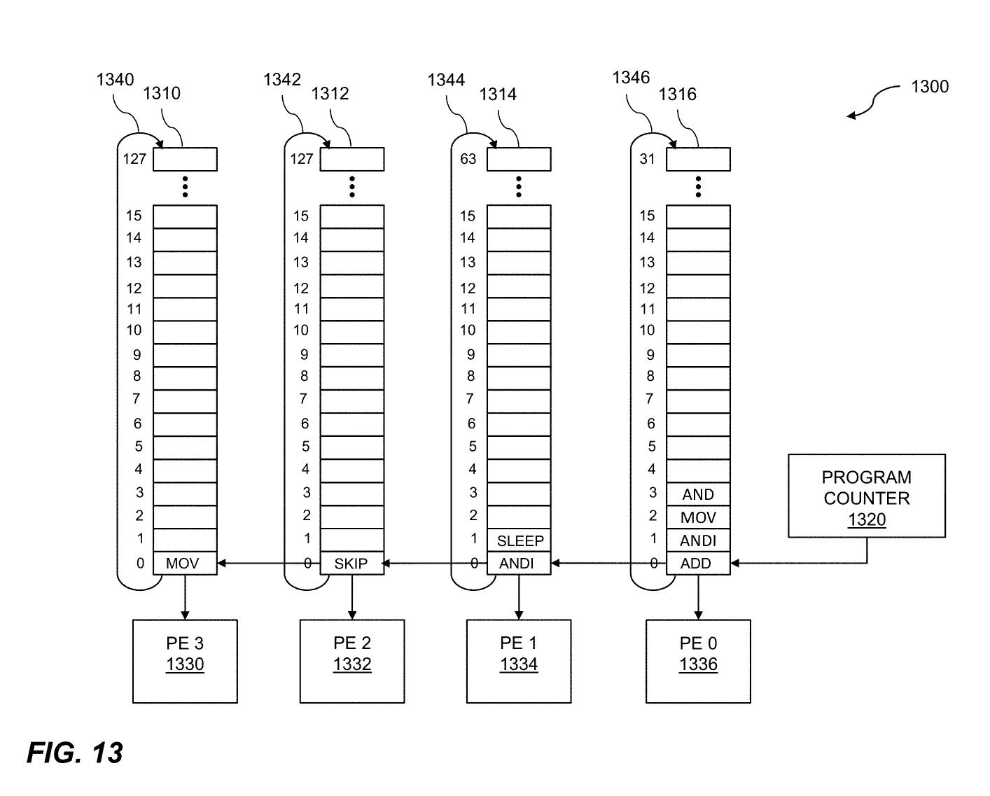

FIG. 13 illustrates a circular buffer and processing elements. A diagram 1300 indicates example instruction execution for processing elements. The processing elements can include a portion of or all of the elements within a reconfigurable fabric. The instruction execution can include instructions for dynamic reconfiguration using data transfer control. A circular buffer 1310 feeds a processing element 1330. A second circular buffer 1312 feeds another processing element 1332. A third circular buffer 1314 feeds another processing element 1334. A fourth circular buffer 1316 feeds another processing element 1336. The four processing elements 1330, 1332, 1334, and 1336 can represent a quad of processing elements. In embodiments, the processing elements 1330, 1332, 1334, and 1336 are controlled by instructions received from the circular buffers 1310, 1312, 1314, and 1316. The circular buffers can be implemented using feedback paths 1340, 1342, 1344, and 1346, respectively. In embodiments, the circular buffer can control the passing of data to a quad of processing elements through switching elements, where each of the quad of processing elements is controlled by four other circular buffers (as shown in the circular buffers 1310, 1312, 1314, and 1316) and where data is passed back through the switching elements from the quad of processing elements where the switching elements are again controlled by the main circular buffer. In embodiments, a program counter 1320 is configured to point to the current instruction within a circular buffer. In embodiments with a configured program counter, the contents of the circular buffer are not shifted or copied to new locations on each instruction cycle. Rather, the program counter 1320 is incremented in each cycle to point to a new location in the circular buffer. The circular buffers 1310, 1312, 1314, and 1316 can contain instructions for the processing elements. The instructions can include, but are not limited to, move instructions, skip instructions, logical AND instructions, logical AND-Invert (e.g. ANDI) instructions, logical OR instructions, mathematical ADD instructions, shift instructions, sleep instructions, and so on. A sleep instruction can be usefully employed in numerous situations. The sleep state can be entered by an instruction within one of the processing elements. One or more of the processing elements can be in a sleep state at any given time. In some embodiments, a “skip” can be performed on an instruction and the instruction in the circular buffer can be ignored and the corresponding operation not performed.

The plurality of circular buffers can have differing lengths. That is, the plurality of circular buffers can comprise circular buffers of differing sizes. In embodiments, the circular buffers 1310 and 1312 have a length of 128 instructions, the circular buffer 1314 has a length of 64 instructions, and the circular buffer 1316 has a length of 32 instructions, but other circular buffer lengths are also possible, and in some embodiments, all buffers have the same length. The plurality of circular buffers that have differing lengths can resynchronize with a zeroth pipeline stage for each of the plurality of circular buffers. The circular buffers of differing sizes can restart at a same time step. In other embodiments, the plurality of circular buffers includes a first circular buffer repeating at one frequency and a second circular buffer repeating at a second frequency. In this situation, the first circular buffer is of one length. When the first circular buffer finishes through a loop, it can restart operation at the beginning, even though the second, longer circular buffer has not yet completed its operations. When the second circular buffer reaches completion of its loop of operations, the second circular buffer can restart operations from its beginning.

As can be seen in FIG. 13, different circular buffers can have different instruction sets within them. For example, circular buffer 1310 contains a MOV instruction. Circular buffer 1312 contains a SKIP instruction. Circular buffer 1314 contains a SLEEP instruction and an ANDI instruction. Circular buffer 1316 contains an AND instruction, a MOVE instruction, an ANDI instruction, and an ADD instruction. The operations performed by the processing elements 1330, 1332, 1334, and 1336 are dynamic and can change over time, based on the instructions loaded into the respective circular buffers. As the circular buffers rotate, new instructions can be executed by the respective processing element.

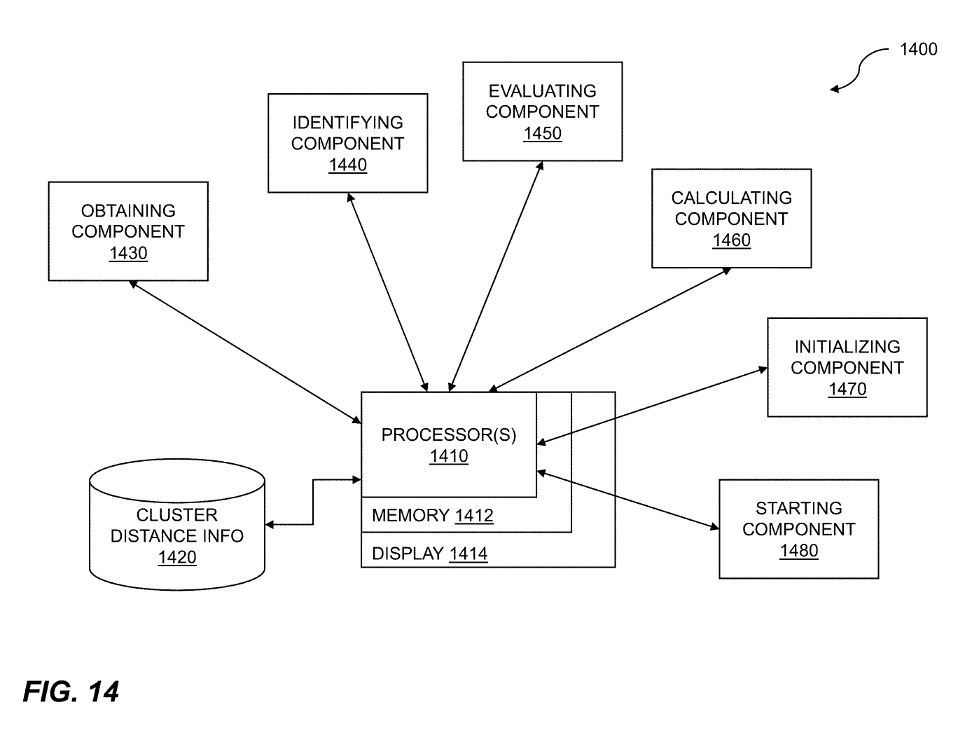

FIG. 14 is a system for circuit synchronization. Information on logical distances between circuits on a semiconductor chip can be obtained. A plurality of clusters within the circuits on the semiconductor chip can be determined, where a cluster within the plurality of clusters can be synchronized to a cycle boundary. A plurality of counter initializations can be calculated, where the counter initializations can compensate for the cycle count separation across the plurality of clusters. A plurality of counters can be initialized, with a counter from the plurality of counters being associated with each cluster from the plurality of clusters, where the counters from the plurality of counters can be distributed across the plurality of clusters, and where the initializing can be based on the counter initializations that were calculated. The plurality of counters can be started to coordinate calculation across the plurality of clusters. The system 1400 can include one or more processors 1410 coupled to a memory 1412 which stores instructions. The system 1400 can include a display 1414 coupled to the one or more processors 1410 for displaying data, intermediate steps, instructions, cluster distance data, and so on. The one or more processors 1410 attached to the memory 1412 where the one or more processors, when executing the instructions which are stored, are configured to: obtain information on logical distances between circuits on a semiconductor chip; determine a plurality of clusters within the circuits on the semiconductor chip, wherein a cluster within the plurality of clusters is synchronized to a cycle boundary; evaluate a cycle count separation across the plurality of clusters using the information on the logical distances; calculate a plurality of counter initializations wherein the counter initializations compensate for the cycle count separation across the plurality of clusters; initialize a plurality of counters, with a counter from the plurality of counters being associated with each cluster from the plurality of clusters, wherein the counters from the plurality of counters are distributed across the plurality of clusters, and wherein the initializing is based on the counter initializations that were calculated; and start the plurality of counters to coordinate calculation across the plurality of clusters.

Integrated circuit information, cluster information, and cluster distance information can be stored in a cluster distance information store 1420. An obtaining component 1430 can obtain information on logical distances between reconfigurable fabric circuits on a semiconductor chip. The distances can be Manhattan distances (steps north, south, east, and west) from an origin. An identifying component 1440 can identify a plurality of clusters within the reconfigurable fabric circuits on the semiconductor chip, wherein a cluster within the plurality of clusters is synchronized to a cycle. A cycle can be an asynchronous, self-timed clock cycle, a clock tick, a chip step, a system step, a hum cycle, an instruction and so on. An evaluating component 1450 can evaluate a cycle count separation across the plurality of clusters using the information on the logical distances. A calculating component 1460 can calculate a plurality of counter initializations wherein the counter initializations compensate for the cycle count separation across the plurality of clusters. An initializing component 1470 can initialize a plurality of counters, with a counter from the plurality of counters being associated with a cluster from the plurality of clusters, wherein the plurality of counters is distributed across the plurality of clusters, and wherein the initializing is based on the counter initializations that were calculated. A starting component 1480 can start the plurality of counters to coordinate configuration across the plurality of clusters.

Thus the system 1400 can comprise a computer system for circuit configuration comprising: a memory which stores instructions; one or more processors attached to the memory wherein the one or more processors, when executing the instructions which are stored, are configured to: obtain information on logical distances between reconfigurable fabric circuits on a semiconductor chip; identify a plurality of clusters within the reconfigurable fabric circuits on the semiconductor chip, wherein a cluster within the plurality of clusters is synchronized to a cycle; evaluate a cycle count separation across the plurality of clusters using the information on the logical distances; calculate a plurality of counter initializations wherein the counter initializations compensate for the cycle count separation across the plurality of clusters; initialize a plurality of counters, with a counter from the plurality of counters being associated with a cluster from the plurality of clusters, wherein the plurality of counters is distributed across the plurality of clusters, and wherein the initializing is based on the counter initializations that were calculated; and start the plurality of counters to coordinate configuration across the plurality of clusters.

In embodiments, a computer program product is embodied in a non-transitory computer readable medium for circuit configuration comprising code which causes one or more processors to perform operations of: obtaining information on logical distances between reconfigurable fabric circuits on a semiconductor chip; identifying a plurality of clusters within the reconfigurable fabric circuits on the semiconductor chip, wherein a cluster within the plurality of clusters is synchronized to a cycle; evaluating a cycle count separation across the plurality of clusters using the information on the logical distances; calculating a plurality of counter initializations wherein the counter initializations compensate for the cycle count separation across the plurality of clusters; initializing a plurality of counters, with a counter from the plurality of counters being associated with a cluster from the plurality of clusters, wherein the plurality of counters is distributed across the plurality of clusters, and wherein the initializing is based on the counter initializations that were calculated; and starting the plurality of counters to coordinate configuration across the plurality of clusters.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are neither limited to conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a technique for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM), an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A processor-implemented method for circuit configuration comprising:
obtaining information on logical distances between reconfigurable fabric circuits on a semiconductor chip;
identifying a plurality of clusters within the reconfigurable fabric circuits on the semiconductor chip, wherein a cluster within the plurality of clusters is synchronized to a cycle;
evaluating a cycle count separation across the plurality of clusters using the information on the logical distances;
calculating a plurality of counter initializations wherein the counter initializations compensate for the cycle count separation across the plurality of clusters;
initializing a plurality of counters, with a counter from the plurality of counters being associated with a cluster from the plurality of clusters, wherein the plurality of counters is distributed across the plurality of clusters, and wherein the initializing is based on the counter initializations that were calculated; and
starting the plurality of counters to coordinate configuration across the plurality of clusters.

2. The method of claim 1 further comprising enabling logical configuration of the plurality of clusters as a function of the initializing of the plurality of counters.

3. The method of claim 2 further comprising performing a logical operation using the reconfigurable fabric based on the logical configuration.

4. The method of claim 3 wherein the logical operation is different from a previous logical operation that was performed using the reconfigurable fabric before the starting of the plurality of counters.

5. The method of claim 1 wherein the plurality of clusters is within a superset of clusters on the reconfigurable fabric.

6. The method of claim 5 wherein only the plurality of clusters within the superset of clusters is reconfigured.

7. The method of claim 6 wherein other clusters within the superset of clusters are not reconfigured.

8. The method of claim 7 wherein the other clusters continue a logical operation while the plurality of clusters is being reconfigured.

9. The method of claim 1 wherein the configuration includes setting the plurality of clusters into a configuration mode.

10. The method of claim 1 wherein the configuration includes causing the plurality of clusters to exit a configuration mode.

11. The method of claim 1 wherein the information on logical distances is calculated based on Manhattan geometry.

12. The method of claim 1 wherein the cycle for the cluster is a tic cycle boundary.

13-14. (canceled)

15. The method of claim 1 wherein the configuration is accomplished by the plurality of clusters entering a configuration mode.

16. The method of claim 15 further comprising loading instructions into the clusters to reconfigure the plurality of clusters.

17. The method of claim 16 wherein the instructions are loaded into circular buffers.

18. The method of claim 17 wherein the circular buffers are statically scheduled.

19. The method of claim 16 wherein the instructions include direct memory access instructions that direct a first set of clusters to accept reconfiguration data.

20. The method of claim 19 further comprising loading reconfiguration data into the plurality of clusters.

21. The method of claim 16 wherein the instructions cause a first set of clusters to execute instructions from internal memory.

22. (canceled)

23. The method of claim 21 further comprising loading reconfiguration data into the first set of clusters.

24. The method of claim 23 wherein the first set of clusters executes instructions from the reconfiguration data after the loading.

25. The method of claim 1 wherein the starting comprises exiting a configuration mode.

26. The method of claim 1 wherein the reconfigurable fabric includes a second set of clusters identified by the identifying.

27-31. (canceled)

32. The method of claim 1 wherein enabling logical configuration of the clusters as a function of the initializing of the counters comprises waiting for the counters to increment to a predetermined value.

33. The method of claim 1 wherein the starting the plurality of counters includes starting a first counter in a first cluster, from the plurality of clusters, followed by starting a second counter in a second cluster, from the plurality of clusters.

34. The method of claim 33 wherein the second cluster is a neighboring cluster, from the plurality of clusters, to the first cluster.

35. A computer program product embodied in a non-transitory computer readable medium for circuit configuration comprising code which causes one or more processors to perform operations of:
obtaining information on logical distances between reconfigurable fabric circuits on a semiconductor chip;
identifying a plurality of clusters within the reconfigurable fabric circuits on the semiconductor chip, wherein a cluster within the plurality of clusters is synchronized to a cycle;
evaluating a cycle count separation across the plurality of clusters using the information on the logical distances;
calculating a plurality of counter initializations wherein the counter initializations compensate for the cycle count separation across the plurality of clusters;
initializing a plurality of counters, with a counter from the plurality of counters being associated with a cluster from the plurality of clusters, wherein the plurality of counters is distributed across the plurality of clusters, and wherein the initializing is based on the counter initializations that were calculated; and
starting the plurality of counters to coordinate configuration across the plurality of clusters.

36. A computer system for circuit configuration comprising:
a memory which stores instructions;
one or more processors attached to the memory wherein the one or more processors, when executing the instructions which are stored, are configured to:
obtain information on logical distances between reconfigurable fabric circuits on a semiconductor chip;
identify a plurality of clusters within the reconfigurable fabric circuits on the semiconductor chip, wherein a cluster within the plurality of clusters is synchronized to a cycle;
evaluate a cycle count separation across the plurality of clusters using the information on the logical distances;
calculate a plurality of counter initializations wherein the counter initializations compensate for the cycle count separation across the plurality of clusters;
initialize a plurality of counters, with a counter from the plurality of counters being associated with a cluster from the plurality of clusters, wherein the plurality of counters is distributed across the plurality of clusters, and wherein the initializing is based on the counter initializations that were calculated; and
start the plurality of counters to coordinate configuration across the plurality of clusters.
